(19) United States
(12) Patent Application Publication
(10) Pub. No.: US 2017/0199217 A1
(43) Pub. Date: Jul. 13, 2017

(54) ELECTRONIC DEVICE, METHOD FOR MANUFACTURING ELECTRONIC DEVICE, AND PHYSICAL-QUANTITY SENSOR

(71) Applicant: Seiko Epson Corporation, Tokyo (JP)

(72) Inventors: Atsuki NARUSE, Shiojiri (JP); Shota KIGURE, Chino (JP)

(21) Appl. No.: 15/393,457

(22) Filed: Dec. 29, 2016

(30) Foreign Application Priority Data
Jan. 13, 2016 (JP) 2016-004165
Jan. 28, 2016 (JP) 2016-014063

(51) Int. Cl. G01P 15/125; B81B 7/04; B81C 1/00

(52) U.S. Cl. CPC G01P 15/125; B81C 1/0023; B81B 7/04; B81C 2203/0792; B81C 2203/0109; B81C 2203/0172; B81B 2207/012; B81B 2207/07; B81B 2203/0118; B81B 2201/0235; B81B 2201/0242; B81B 2201/0264

(57) ABSTRACT

An electronic device includes a package; and a functional element, in which a side surface of the functional element is fixed to a side wall of the package on an inner side thereof via an adhesive.

### BACKGROUND

1. Technical Field

The present invention relates to an electronic device, a method for manufacturing electronic device, and a physical-quantity sensor.

2. Related Art

In the related art, in an electronic device in which a sensor chip is fixed on an inner bottom surface of a package via an adhesive, temperature characteristics are known to be degraded when thermal stress produced due to a difference in coefficient of thermal expansion between the package and the sensor chip is transmitted to the sensor chip.

Therefore, JP-A-2002-214057 proposes a pressure sensor that is provided with a base between a package and a sensor chip, in which the base is formed to have a first layer that has a coefficient of thermal expansion equivalent to that of a sensor chip and is bonded to the sensor chip, and a second layer that has a coefficient of thermal expansion which is equivalent to that of the sensor chip and has the elastic modulus which is higher than that of the first layer, and thereby thermal stress that is transmitted from the package to the sensor chip decreases.

In addition, in the related art, there has been known a capacitance type physical-quantity sensor that includes a sensor element provided with a fixed electrode disposed to be fixed to a substrate, a movable electrode provided to face the fixed electrode at intervals and to be capable of shifting, and a support that is supported by the substrate, and that detects a physical quantity such as acceleration or angular velocity, based on capacitance between the fixed electrode and the movable electrode.

For example, a sensor element of a physical-quantity sensor according to JP-A-2006-250702 includes a movable electrode portion disposed to be interposed between a pair of fixed electrode portions. In the physical-quantity sensor, each of the fixed electrode portions has one end fixed to a front surface of a substrate and has a plurality of fixed electrodes having a comb-teeth shape which are connected to each other by a connecting portion. Meanwhile, the movable electrode portion has a plurality of movable electrodes having the comb-teeth shape on a side facing the fixed electrode portions and has both ends which are supported, respectively, by two supports fixed to the front surface of the substrate via a beam portion.

For example, in the physical-quantity sensor in which the substrate that supports the sensor element is fixed to the package via the adhesive, when the package is deformed due to an external stress, the substrate is likely to be deformed via the adhesive. In addition, when ambient temperature changes, the substrate is deformed due to a difference in coefficient of thermal expansion between the substrate and the adhesive and the temperature characteristics of the physical-quantity sensor are degraded. As a result, a problem arises in that the physical-quantity sensor has low measurement accuracy. Then, in the physical-quantity sensor according to JP-A-2006-250702, the substrate (glass substrate) is provided with a counterbore such that an area, on which the adhesive is applied between the package and the substrate, is reduced, and thereby deformation of the substrate due to the external stress or the difference in coefficient of thermal expansion is reduced such that reduction in degradation of detection accuracy is achieved.

However, in an electronic device such as the pressure sensor disclosed in JP-A-2002-214057, in order to reduce the transmission of the thermal stress produced between the sensor chip and the package to the sensor chip such that the electronic device has good temperature characteristics, the base having the two-layer structure is disposed between the sensor chip and the package. As a result, since it is necessary to form a thick package due to the thickness of the base having the two-layer structure, a problem arises in that it is difficult to achieve an electronic device having good temperature characteristics with a low profile.

In addition, in the physical-quantity sensor disclosed in JP-A-2006-250702, the fixed electrode portions and the supports, which support the movable electrode portion of the sensor element, are positioned to overlap each other in a plane in a region in which the adhesive, which fixes the substrate to the package, is applied. Therefore, in a case where the package is deformed due to the external stress or in a case where ambient temperature changes and thus the glass substrate is deformed due to the difference in coefficient of thermal expansion between the substrate and the adhesive, a region of the glass substrate, to which the fixed electrode portion and the support are fixed, is also deformed. Thus, the sensor element performs detection with low accuracy. Hence, a physical-quantity sensor that is capable of detecting a physical quantity with higher accuracy with respect to the external stress or a change in the ambient temperature is demanded.

### SUMMARY

The invention can be realized in the following aspects or application examples.

### APPLICATION EXAMPLE 1

According to this application example, there is provided an electronic device including a package; and a functional element, in which a side surface of the functional element is fixed to a side wall of the package on an inner side thereof via an adhesive.

In this configuration, compared to a case where an underside of the functional element is fixed to an inner bottom surface of the package, the side surface having high stiffness against bending is fixed, and thereby it is possible to reduce an occurrence of transmission, to the functional element, of strain produced due to thermal stress produced when the functional element and the package are fixed to each other with the adhesive. Hence, since it is not necessary to increase the package in thickness in consideration of a space of a base or the like into which a material that releases the stress, is inserted, it is possible to achieve a low profile of the package and it is possible to obtain an electronic device having good temperature characteristics.

### APPLICATION EXAMPLE 2

In the electronic device according to the application example, the functional element may be fixed to the side wall to which one side surface of the functional element is fixed.

In this configuration, compared to a case where a plurality of side surfaces of the functional element is fixed, it is possible to limit a range of stress that is transmitted to the functional element from the package. Thus, it is possible to release the strain produced due to the thermal stress transmitted to the functional element from the package such that it is possible to reduce the strain of the functional element. As a result, it is possible to obtain the electronic device having good temperature characteristics.

### APPLICATION EXAMPLE 3

In the electronic device according to the application example, the functional element may be fixed to the side wall to which a part of the one side surface of the functional element is fixed.

In this configuration, compared to a case where the entire range of the side surface of the functional element is fixed, it is possible to reduce thermal stress that is transmitted to the functional element from the package. As a result, it is possible to obtain the electronic device having good temperature characteristics.

### APPLICATION EXAMPLE 4

In the electronic device according to the application example, the functional element may abut on an inner bottom surface of the package.

In this configuration, the heat can be transmitted through the inner bottom surface with which the functional element and the package are in contact, in addition to the side surface of the functional element which is fixed to the side wall of the package on the inner side thereof. In this manner, compared to a case where the functional element does not abut on the inner bottom surface of the package, it is possible to rapidly release a heat gradient between the package and the functional element. Hence, it is possible to obtain the electronic device having good temperature characteristics.

### APPLICATION EXAMPLE 5

In the electronic device according to the application example, the package may be formed of a material containing a ceramic.

In this configuration, compared to a case where the package is formed of a resin-based material, the package has a good heat resistance, and low hygroscopicity. Therefore, it is possible to obtain stable thermal expansion behavior of the package. As a result, it is possible to obtain the electronic device having good temperature characteristics.

### APPLICATION EXAMPLE 6

In the electronic device according to the application example, the functional element may have a substrate and the substrate may be formed of a material containing borosilicate glass.

In this configuration, compared to a case where the substrate of the functional element is formed of a semiconductor material such as silicon, as a main material, it is possible to obtain high elastic modulus. As a result, it is possible to reduce the strain produced due to the thermal stress produced when the functional element is fixed to the package with the adhesive such that it is possible to obtain the electronic device having good temperature characteristics.

### APPLICATION EXAMPLE 7

In the electronic device according to the application example, a base compound of the adhesive may be formed of a resin-based material.

In this configuration, even in adhesion between different types of materials such as a ceramic or glass, it is possible to obtain stable adhesion strength. In addition, since the resin is a soft material compared to an inorganic material, the adhesive functions as a stress releasing layer. As a result, it is possible to release the thermal stress produced due to a difference in coefficient of thermal expansion between the functional element and the package such that it is possible to obtain the electronic device having good temperature characteristics.

### APPLICATION EXAMPLE 8

In the electronic device according to the application example, a base compound of the adhesive may be formed of an inorganic material.

In this configuration, the adhesive can have the coefficient of thermal expansion close to that of the ceramic and glass. As a result, compared to an adhesive formed of a resin-based material, it is possible to release the thermal stress produced due to a difference in coefficient of thermal expansion between the functional element and the package. Thus, it is possible to obtain the electronic device having good temperature characteristics.

### APPLICATION EXAMPLE 9

According to this application example, there is provided a method for manufacturing an electronic device including: applying an adhesive on a side surface of a functional element; fixing the side surface of the functional element to a side surface of a package on an inner side thereof; curing the adhesive; fixing an IC to the functional element; electrically connecting the functional element and the IC; electrically connecting the package and the IC; and mounting and sealing a lid member on the package.

In this method, compared to a case where an underside of the functional element is fixed to an inner bottom surface of the package when the package and the functional element are fixed to each other with the adhesive, it is possible to release thermal stress produced due to the difference in coefficient of thermal expansion between the functional element and the package such that it is possible to reduce an occurrence of transmission of the thermal stress to the functional element. Hence, since it is not necessary to increase the package in thickness in consideration of a space of a base or the like into which a material that releases the stress, is inserted, it is possible to achieve a low profile of the package and it is possible to provide a method for manufacturing the electronic device having good temperature characteristics.

### APPLICATION EXAMPLE 10

According to this application example, there is provided a physical-quantity sensor including: a first substrate; a second substrate fixed on the first substrate via the adhesive; and a sensor element disposed on the second substrate. The sensor element is provided with a fixed electrode portion fixed to the second substrate, and a support that fixes a movable electrode portion to be movable and is fixed to the second substrate, and the adhesive is disposed on one side of an outer peripheral portion of the second substrate so as not to overlap the fixed electrode portion and the support when the second substrate is viewed in a plan view.

In this configuration, since the adhesive that fixes the second substrate on the first substrate is disposed in one side of the second substrate of the outer peripheral portion, deformation of the second substrate is reduced in a portion other than the one side of the outer peripheral portion in a case where the deformation of the first substrate due to the external stress is transmitted to the second substrate via the adhesive, or in a case where the second substrate is deformed due to the difference in coefficient of thermal expansion between the adhesive and the second substrate. Since the adhesive is disposed so as not to overlap the fixed electrode portion and the support of the sensor element when the second substrate is viewed in a plan view, even the deformation of the second substrate is unlikely to have an effect on the fixed electrode portion and the support of the sensor element. Hence, it is possible to provide the physical-quantity sensor that is capable of detecting a physical quantity with higher accuracy with respect to the external stress or a change in the ambient temperature.

### APPLICATION EXAMPLE 11

In the physical-quantity sensor according to the application example, the one side of the second substrate may be provided with a terminal unit that is connected to the outside, and the terminal unit may be disposed to overlap the adhesive when the second substrate is viewed in the plan view.

In this configuration, the terminal unit provided on the one side of the second substrate is disposed to overlap the adhesive when the second substrate is viewed in the plan view. Since the terminal unit has a small influence on measurement accuracy of the sensor element, the measurement accuracy of the sensor element is not influenced even when the one side of the second substrate is deformed. In addition, the terminal unit is disposed on one side of the second substrate, and thereby it is possible to dispose the fixed electrode portion and the support of the sensor element at a position farther separated from a region on which the adhesive is applied. In this manner, it is possible to increase the accuracy of the physical-quantity sensor.

### APPLICATION EXAMPLE 12

In the physical-quantity sensor according to the application example, the sensor element may be configured to have a first sensor element having a detecting direction in a first direction along a main surface of the second substrate, a second sensor element having a detecting direction in a second direction intersecting with the first direction along the main surface of the second substrate, and a third sensor element having a detecting direction in a third direction intersecting with the first direction and the second direction, and the third sensor element may be disposed in a region farther separated from the one side than the first sensor element and the second sensor element.

In this configuration, the physical-quantity sensor has three sensor elements that detect three directions different from each other, in which the third sensor element, which detects the third direction intersecting with a main surface of the second substrate, is disposed in the region farther separated from the one side of the second substrate than the first sensor element and the second sensor element which have detecting directions in directions along the main surface of the second substrate. The third sensor element has the detecting direction in the third direction intersecting with the main surface of the second substrate to which the fixed electrode portion is fixed, that is, a thickness direction of the second substrate. In a case where the deformation of the first substrate due to the external stress is transmitted to the second substrate via the adhesive, or in a case where the second substrate is deformed due to the difference in coefficient of thermal expansion between the adhesive and the second substrate, the second substrate is deformed in the thickness direction. Therefore, the third sensor element having the detecting direction in the thickness direction of the second substrate is likely to have degradation in the accuracy of the sensor due to the deformation of the second substrate, compared to the first sensor element and the second sensor element that have the detecting directions in directions along the main surface of the second substrate. The third sensor element is farther separated from the one side of the second substrate on which the adhesive is disposed, than the other sensor elements, and thereby the degradation in the accuracy of the third sensor element due to the deformation of the second substrate is reduced. As a result, it is possible to increase the accuracy of the physical-quantity sensor.

### APPLICATION EXAMPLE 13

The electronic apparatus according to the application example includes the electronic device or the physical-quantity sensor according to the application example described above.

In this configuration, it is possible to provide an electronic apparatus that is highly reliable because the apparatus includes the electronic device having high accuracy or the physical-quantity sensor.

### APPLICATION EXAMPLE 14

The moving object according to the application example includes the electronic device or the physical-quantity sensor according to the application example described above.

In this configuration, it is possible to provide a moving object that is highly reliable because the moving object includes the electronic device having high accuracy or the physical-quantity sensor.

### BRIEF DESCRIPTION OF THE DRAWINGS

The invention will be described with reference to the accompanying drawings, wherein like numbers reference like elements.

FIG. 1 is a plan view illustrating a schematic configuration of an accelerometer according to Embodiment 1.

FIG. 2 is a sectional view illustrating a schematic configuration of the accelerometer.

FIG. 3 is a plan view schematically illustrating a sensor element.

FIG. 4 is a perspective view schematically illustrating a fixing state of the sensor element and a package.

FIG. 5 is a process flowchart illustrating a method for manufacturing the accelerometer.

FIG. 6 is a process view schematically illustrating a process of preparing the sensor element.

FIG. 7 is a process view schematically illustrating a process of applying an adhesive.

FIG. 8 is a process view schematically illustrating a process of fixing the sensor element.

FIG. 9 is a process view schematically illustrating a process of fixing an IC.

FIG. 10 is a process view schematically illustrating a process of wire bonding.

FIG. 11 is a process view schematically illustrating a process of sealing.

FIG. 12 is a plan view of an inside of a package according to Modification Example 1.

FIG. 13 is a plan view illustrating a side wall of a package on the inner side thereof according to Modification Example 2.

FIG. 14 is a sectional view schematically illustrating a physical-quantity sensor according to Embodiment 2.

FIG. 15 is a plan view illustrating the physical-quantity sensor according to Embodiment 2.

FIG. 16 is a sectional view taken along line XVI-XVI in FIG. 15.

FIG. 17 is a sectional view taken along line XVII-XVII in FIG. 15.

FIG. 18 is a plan view illustrating a first sensor element.

FIG. 19 is a plan view illustrating a third sensor element.

FIG. 20 is a plan view illustrating a physical-quantity sensor according to Embodiment 3.

FIG. 21 is a perspective view schematically illustrating an electronic apparatus according to Embodiment 4.

FIG. 22 is a perspective view schematically illustrating another electronic apparatus according to Embodiment 4.

FIG. 23 is a perspective view schematically illustrating still another electronic apparatus according to Embodiment 4.

FIG. 24 is a perspective view schematically illustrating a moving object according to Embodiment 5.

### DESCRIPTION OF EXEMPLARY EMBODIMENTS

Hereinafter, specific embodiments of the invention will be described with reference to the figures. Note that, in the following figures, for easy understanding of the description, the configurational elements are illustrated to have a size to the extent that the elements can be recognized on the figure, and thus the configurational elements are drawn to have a scale which is different from a real scale in some cases.

### Embodiment 1

### Configuration of Accelerometer

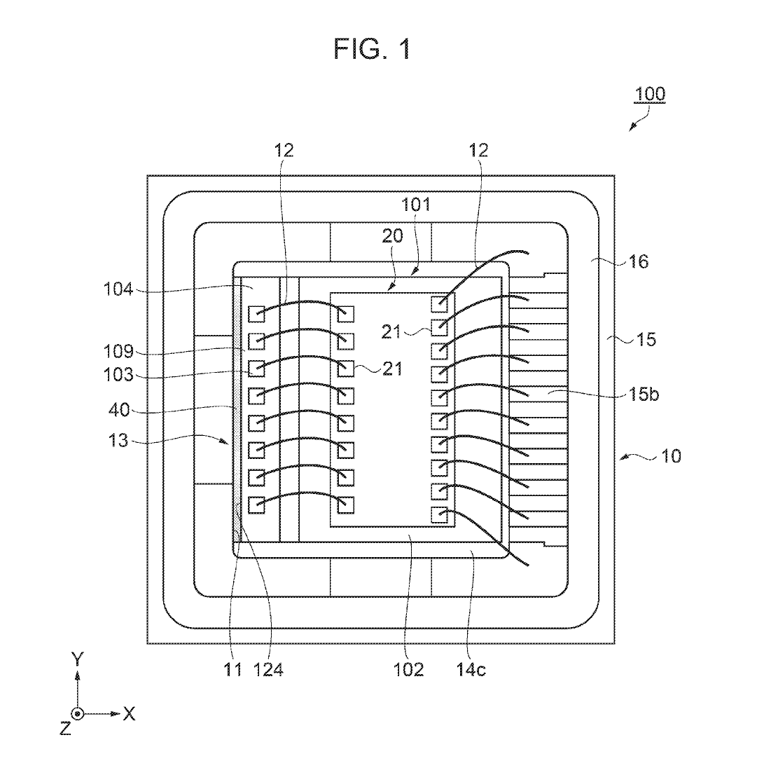

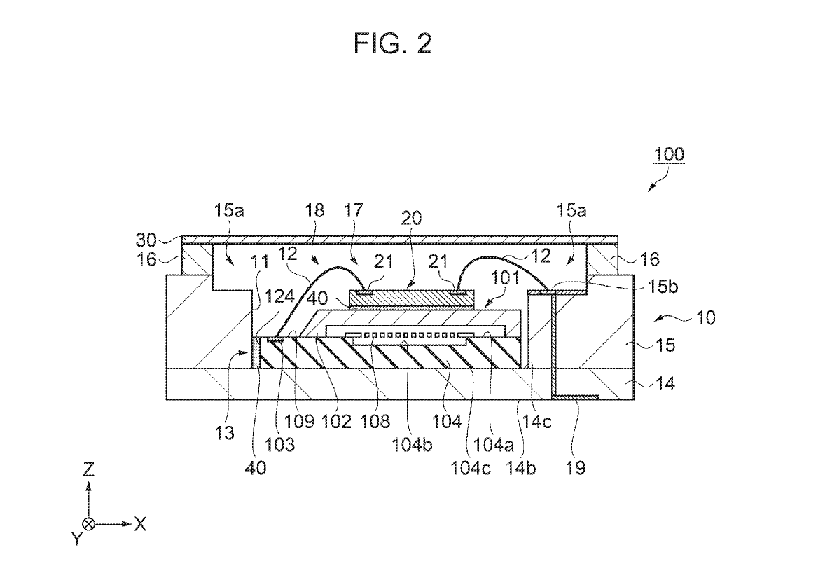

A configuration of an accelerometer as an electronic device according to Embodiment 1 of the invention is described with reference to FIGS. 1 and 2. FIG. 1 is a plan view schematically illustrating the accelerometer according to Embodiment 1. FIG. 2 is a sectional view schematically illustrating the accelerometer. FIG. 1 is a plan view in which a lid (lid member) is omitted (transparent).

In the figures, with a sensor element which is a functional element, as a reference, a direction, in which the lid as the cover member is disposed, is an upward direction, a direction, in which a bottom plate of the package is disposed, is a downward direction, on members such as the sensor element, the bottom plate, a side wall, or an IC, a surface of the member disposed in the upward direction is an upper surface and a surface of the member disposed in the downward direction is an underside.

In addition, a Y-axial direction is a direction in which terminal electrodes 103 are aligned, an X-axial direction is a direction orthogonal to the Y-axial direction when a sensor element (functional element) 101 is viewed in a plan view, and a Z-axial direction is a direction orthogonal to the X-axial direction and the Y-axial direction.

As illustrated in FIGS. 1 and 2, an accelerometer 100 includes the sensor elements 101, a package 10, an integrated circuit (IC) 20, and a lid 30. The sensor element 101 is accommodated in the package 10 and is fixed to a side wall 11 of the package 10 on the inner side in a fixing portion 13 via an adhesive 40.

Hereinafter, the package 10, the IC 20, the lid 30, a configuration of the sensor element 101, an operation of the accelerometer 100, and the fixing portion 13 of the sensor element 101 will be described in this order in detail.

### Package

As illustrated in FIGS. 1 and 2, the package 10 includes a plate-shaped bottom plate 14, a frame-shaped side wall 15, and a seal ring 16.

The package 10 is formed of a material having a coefficient of thermal expansion which is equal to or as close as possible to the coefficient of thermal expansion of the sensor element 101 or the lid 30, and is formed of using a ceramic in the embodiment. The package 10 is formed of stacking and sintering green sheets molded to have a predetermined shape. For example, the green sheet is formed as follows. Powder of the ceramic is dispersed in a predetermined solution, a binder is added to the ceramic-dispersed solution, and a kneaded material is generated and is shaped to have a sheet shape.

The package 10 accommodates the sensor element 101 and the IC 20 and thus has a recessed portion 17 opened upward. The recessed portion 17 blocked with the lid 30 that is bonded to the side wall 15 via the seal ring 16 becomes a sealed inner space 18 in which the sensor element 101, the IC 20, and the like are accommodated.

The sealed inner space 18 has an inside pressure which can be set to predetermined atmosphere. For example, the inner space 18 is filled with nitrogen gas so as to have atmospheric pressure, or is in vacuum state (a state of a space filled with gas in pressure (1×10⁵ Pa to 1×10⁻¹⁰ Pa (JISZ 8126-1: 1999)) which is lower than the normal atmospheric pressure), and thereby it is possible to more stably detect an acceleration.

The side wall 15 is provided to have a substantially circumferential rectangular shape at an outer circumferential edge of an upper surface of the bottom plate 14. The seal ring 16 formed of metal such as kovar is provided on the upper surface of the side wall 15. The seal ring 16 has a function as a bonding member of the side wall and the lid 30 and is provided to have a frame shape (substantially circumferential rectangular shape) along the upper surface of the side wall 15.

A pad 15b is formed in a recessed portion 15a formed on the upper surface of the side wall 15. The pad 15b is formed as follows. For example, a conductive paste of silver·palladium or the like, tungsten metallization, or the like is used, a required shape is formed and then burning is performed, and then the burned material is plated with nickel and gold or silver.

The pad 15b is disposed to correspond to the IC 20 which will be described below. An external terminal electrode 19 as a metal layer is disposed on the underside 14b of the bottom plate 14. For example, the external terminal electrode 19 is formed by plating a burned layer of silver·palladium or the like with nickel and gold or silver. The pad 15b is electrically connected to the external terminal electrode 19.

### IC

As illustrated in FIG. 2, the IC 20 is fixed on a cap 102 of the sensor element 101 via the adhesive 40. In addition, the IC 20 includes a circuit that drives the sensor element 101 and a circuit that detects the acceleration.

A bonding pad 21 for electrical connection is provided on the upper surface of the IC 20. The bonding pad 21 is electrically connected to the pad 15b provided on the package 10, for example, through a wire 12 as a connection member using a wire bonding method and is further electrically connected to portions of the sensor element 101 via the terminal electrode 103 which will be described below, or the like.

Note that, instead of the wire 12 as the connection member, for example, both pads may be electrically connected through direct bonding using a gold pad or the like.

### Lid

As illustrated in FIG. 2, the lid 30 is a plate-shaped member, blocks an opening of the recessed portion 17 that opens on the upper side of the package 10, and, for example, bonding is performed on the periphery of the recessed portion 17 by using a seam welding method. Since the lid 30 of the embodiment has a plate shape, it is easy to form the lid and the lid has good shape stability.

The lid 30 is formed of using a plate material of kovar. The use of the plate material of kovar in the lid 30 enables the seal ring 16 and the lid 30 which are formed of kovar to melt in the same melting state when sealing is performed, and further alloying is easily performed and thus it is possible to easily and reliably perform sealing.

In addition, the lid 30 may be formed of using a plate member formed of another material instead of kovar, and, for example, using metal material such as an alloy 42 or stainless steel, the same material as the side wall 15 of the package 10, or the like.

### Structure of Sensor Element

Next, the structure of the sensor element 101 of the embodiment will be described.

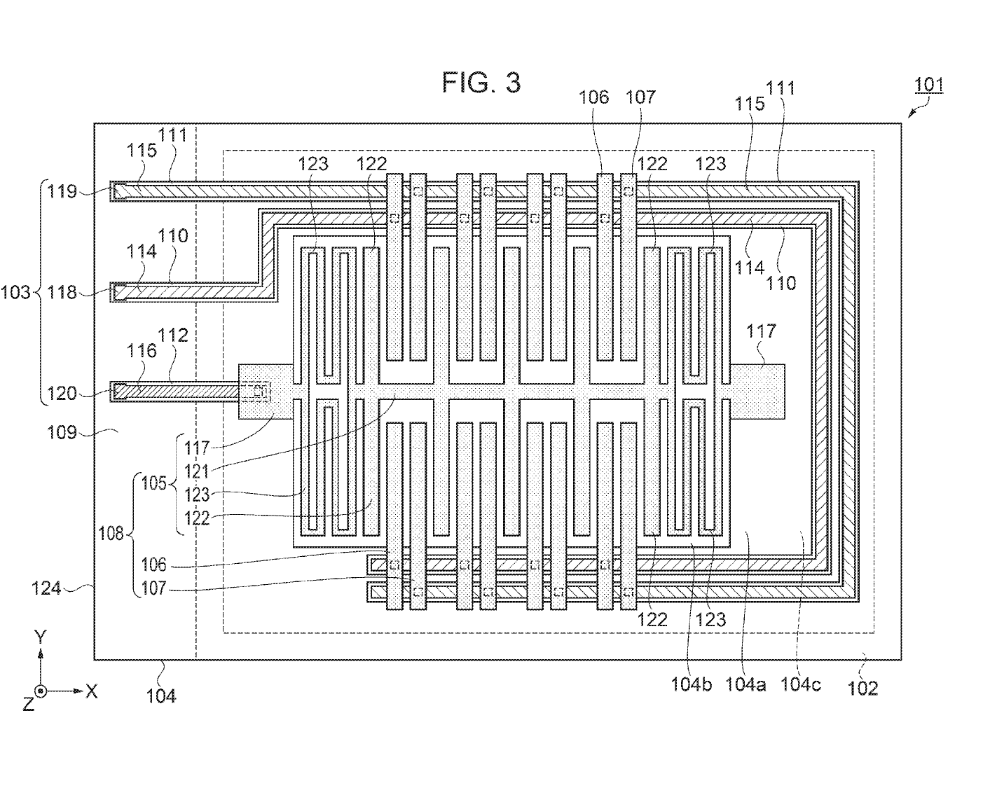

FIG. 3 is a plan view schematically illustrating the sensor element 101. FIG. 3 is a view schematically illustrating the sensor element 101 that detects acceleration of a single axis and some configurational elements are omitted from FIG. 3, for convenience of the description. In addition, an X axis, a Y axis, and a Z axis in the figures are coordinate axes orthogonal to each other and a direction of an arrow means+(plus).

As illustrated in FIG. 3, the sensor element 101 includes the cap 102, a substrate 104, a movable portion 105, a first fixed electrode finger 106, and a second fixed electrode finger 107. Hereinafter, the movable portion 105, the first fixed electrode finger 106, and the second fixed electrode finger 107 are collectively referred to as a semiconductor substrate 108.

The substrate 104 is a substantially rectangular-shaped flat plate orthogonal to the Z-axial direction, and has an upper surface 104a on which a plurality of first fixed electrode fingers 106, the second fixed electrode finger 107, or the like is bonded. The upper surface 104a is provided with a terminal portion 109 at the end portion in the −(minus) X-axial direction, and a region except for the terminal portion 109 is covered with the cap 102 having a recessed portion on the upper surface 104a side.

It is desirable that a constituent material of the cap 102 is a material such as low-resistance silicon having conductivity. The cap 102 having conductivity is connected to the ground, and thereby electrostatic shielding is performed such that it is possible to block electromagnetic waves that are propagated to the inside of the sensor element 101 from the outside of the cap 102. In this manner, it is possible to reduce signal noise due to the electromagnetic wave.

It is possible to fix the cap 102 to the upper surface 104a of the substrate 104, for example, through a anodic bonding method, a direct bonding method, and an adhesive. In particular, a constituent material of the substrate 104 is glass containing alkali metal ions and thus it is possible to fix the cap 102 to the upper surface 104a of the substrate 104 through the anodic bonding method, in a case where constituent materials of the cap 102 contain the semiconductor material such as silicon as a main material.

Since it is possible to perform the anodic bonding method at a lower temperature, compared to the direct bonding method, it is possible to reduce residual stress produced when the cap 102 is fixed to the upper surface 104a of the substrate 104. In addition, since the anodic bonding method is performed with a smaller adhesion width, compared to a method of fixing with an adhesive, it is possible to decrease the accelerometer 100 in size.

In addition, in order to avoid interfering between the substrate 104 and the movable portion 105, a recessed portion 104b having a substantially rectangular shape of a plane shape is provided substantially at the central portion of the upper surface 104a of the substrate 104 (refer to FIG. 2). In this manner, it is possible to position a region, in which the movable portion 105 is movable, within the recessed portion 104b in a plan view.

The upper surface 104a of the substrate 104 is provided with a first groove 110 along the outer periphery of the recessed portion 104b, and a second groove 111 along the outer periphery of the first groove 110. In addition, a third groove 112 is provided on the terminal portion 109 side of the upper surface 104a of the substrate 104 and on a side opposite to the second groove 111 with the first groove 110 interposed therebetween.

The first groove 110 and the second groove 111 extend to surround the recessed portion 104b in a counterclockwise direction from a −Y-axial direction side of the recessed portion 104b to the terminal portion 109 on a −X-axial direction side of the recessed portion 104b. The third groove 112 is provided to the terminal portion 109 from the −X-axial direction side of the recessed portion 104b along the first groove 110 and the second groove 111.

As a constituent material of the substrate 104, preferably, an insulating material such as glass, high resistivity silicon, or the like is used. In particular, in a case where the semiconductor substrate 108 is formed of a semiconductor material such as silicon as a main material, preferably, glass containing alkali metal ions (movable ions), for example, borosilicate glass such as Pyrex (registered trademark) is used as the constituent material of the substrate 104.

In this manner, in the sensor element 101, it is possible to perform the anodic bonding on the substrate 104 and the semiconductor substrate 108. In addition, in the sensor element 101, the glass containing the alkali metal ions is used for the substrate 104, and thereby it is possible to easily perform insulation separation on the substrate 104 from the semiconductor substrate 108.

In addition, the substrate 104 may not necessarily have insulation properties, and, for example, may be a semiconductor substrate formed of resistivity silicon. In this case, the insulation separation is performed between the substrate 104 and the semiconductor substrate 108 with an insulation film therebetween.

Preferably, there is a small difference in coefficient of thermal expansion between the constituent materials of the substrate 104 and the constituent materials of the semiconductor substrate 108, specifically, the difference in coefficient of thermal expansion between the constituent materials of the substrate 104 and the constituent materials of the semiconductor substrate 108 is, preferably, 3 ppm/° C. or lower. In this manner, in the sensor element 101, it is possible to decrease the residual stress between the substrate 104 and the semiconductor substrate 108.

First wiring 114 is provided on the bottom surface (bottom) of the first groove 110 along the first groove 110, second wiring 115 is provided on the bottom surface of the second groove 111, along the second groove 111, and third wiring 116 is provided on the bottom surface of the third groove 112 along the third groove 112.

The first wiring 114 is wiring that is electrically connected to the first fixed electrode finger 106, the second wiring 115 is wiring that is electrically connected to the second fixed electrode finger 107, and the third wiring 116 is wiring that is electrically connected to an anchor 117 which will be described below.

In addition, end portions (end portions disposed on the terminal portion 109) of the first wiring 114, the second wiring 115, and the third wiring 116 are a first terminal electrode 118, a second terminal electrode 119, and a third terminal electrode 120. Hereinafter, the first terminal electrode 118, the second terminal electrode 119, and the third terminal electrode 120 are collectively referred to as the terminal electrode 103.

As constituent materials of the first wiring 114, the second wiring 115, and the third wiring 116, there is no particular limitation to the materials as long as the materials have conductivity, and it is possible to use various electrode materials. Examples of the constituent materials of the first wiring 114, the second wiring 115, and the third wiring 116 include, for example, oxides (transparent electrode material) such as indium tin oxide (ITO), indium zinc oxide (IZO), In₃O₃, SnO₂, SnO₂ containing Sb, or ZnO containing Al, Au, Pt, Ag, Cu, Al, or an alloy containing the substances described above, and it is possible to use a combination of one or more types of substances.

In the embodiment, Pt is used as the constituent material of the first wiring 114, the second wiring 115, and the third wiring 116. In the case of using Pt, in order to improve adhesiveness to the substrate 104, it is preferable to use Ti as a base material.

In addition, in a case where the constituent material of the wiring is a transparent electrode material, particularly, that is, ITO, and the substrate 104 is transparent, it is possible to easily recognize a foreign substance presented on the surfaces of the first fixed electrode finger 106 and the second fixed electrode finger 107 from the surface on the underside 104c side of the substrate 104, and the sensor element 101 is capable of performing efficient detection.

The movable portion 105 is configured to have an arm 121, a movable electrode finger 122, a flexible portion 123, and the anchor 117. Here, the arm 121, the movable electrode finger 122, and the flexible portion 123 are disposed at positions facing the recessed portion 104b of the substrate 104, that is, at positions within the recessed portion 104b viewed in the Z-axial direction.

As illustrated in FIG. 3, the arm 121 extends to have a beam shape (column shape) in the X-axial direction and is provided with the flexible portion 123 at both ends in the X-axial direction. A plurality of movable electrode fingers 122 are provided to form a comb-teeth shape in a direction (Y-axial direction) orthogonal to an extending direction of the arm 121 at regular intervals in the extending direction of the arm 121.

The flexible portion 123 extends in the X-axial direction while bending in the Y-axial direction, and is formed to bend (be deformed) in the X-axial direction due to an external force that is applied in the X-axial direction.

The anchor 117 is connected to both end portions of the flexible portion 123 and is bonded to the substrate 104. The anchor 117 positioned to be closer to the −X-axial direction side than the recessed portion 104b is disposed at a position at which the anchor covers the third groove 112 of the substrate 104.

The first fixed electrode finger 106 is disposed at a position at which the first fixed electrode finger covers the first groove 110 and the second groove 111 of the substrate 104. In addition, the first fixed electrode finger 106 is disposed to have a part that overlaps the recessed portion 104b in a plan view from the Z-axial direction.

The second fixed electrode finger 107 is disposed to be parallel to the first fixed electrode fingers 106 and is disposed at the position at which the second fixed electrode finger covers the first groove 110 and the second groove 111 of the substrate 104. In addition, similar to the first fixed electrode finger 106, the second fixed electrode finger 107 is disposed to have a part that overlaps the recessed portion 104b when viewed in the Z-axial direction.

The first fixed electrode finger 106 and the second fixed electrode finger 107 are disposed to be interposed between the movable electrode fingers 122 which are disposed to have a comb-teeth shape.

The direct bonding method includes a plasma-activated low-temperature bonding method, in which, in order to have a low temperature, the front surface of the substrate, which is bonded, is irradiated with plasma and is bonded. In this manner, similar to the anodic bonding, since the bonding is performed at low temperature, it is possible to reduce residual stress produced when the cap 102 is fixed to the upper surface 104a of the substrate 104. Further, since it is possible to have a smaller adhesion width, it is possible to decrease the accelerometer 100 in size.

The sensor element 101 is not limited to the accelerometer 100, and, for example, may configure a gyro sensor, a pressure sensor, or the like by providing an angular-velocity detecting circuit, a pressure detecting circuit, or the like to the IC 20.

### Operation of Accelerometer

Next, an operation of the accelerometer 100 will be described.

As illustrated in FIG. 3, the sensor element 101 is provided with a first capacitor formed between the first fixed electrode finger 106 and the movable electrode finger 122 facing the first fixed electrode finger 106 from the −X-axial direction side, and a second capacitor formed between the second fixed electrode finger 107 and the movable electrode finger 122 facing the second fixed electrode finger 107 from the +X-axial direction side.

In this state, when an acceleration, for example, is applied to the sensor element 101 in the −X-axial direction, the arm 121 and the movable electrode finger 122 are shifted in the +X-axial direction due to the inertia. At this time, since there are narrow intervals between the first fixed electrode finger 106 and the movable electrode finger 122, capacitance of the first capacitor increases. In addition, since there are wide intervals between the second fixed electrode finger 107 and the movable electrode finger 122, capacitance of the second capacitor decreases.

Conversely, when an acceleration is applied in the +X-axial direction, and the arm 121 and the movable electrode finger 122 are shifted in the −X-axial direction, the capacitance of the first capacitor decreases and the capacitance of the second capacitor increases.

Hence, the sensor element 101 detects a difference between a change in the capacitance of the first capacitor which is detected between the first terminal electrode 118 and the third terminal electrode 120 and a change in the capacitance of the second capacitor which is detected between the second terminal electrode 119 and the third terminal electrode 120, and thereby is capable of detecting a size and direction of a physical quantity such as the acceleration that is applied to the sensor element 101.

Since the sensor element 101 detects a difference between changes in the capacitances of the two capacitors (the first capacitor and the second capacitor), it is possible to detect the physical quantity such as the acceleration with high sensitivity.

### Fixing Portion of Sensor Element

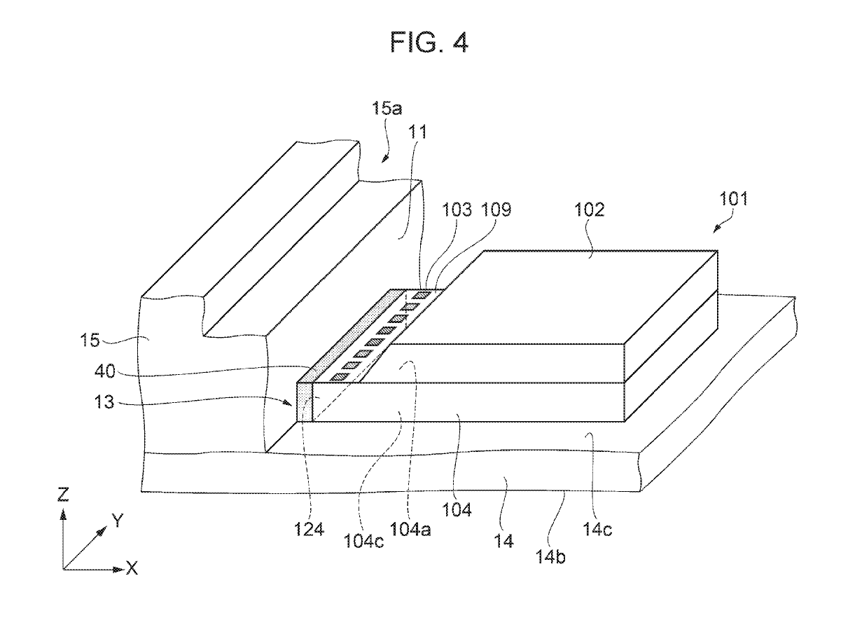

FIG. 4 is a perspective view schematically illustrating the fixing state of the sensor element and the package. For convenience of description, FIG. 4 illustrates the side wall 11 to which the sensor element 101 is fixed, of the side wall 11 of the package 10 on the inner side, the sensor element 101, and an inner bottom surface 14c of the package 10.

As illustrated in FIG. 4, in the sensor element 101, one side surface 124 of the substrate 104 is fixed to the side wall 11 of the package 10 on the inner side via the adhesive 40. The adhesive 40 is applied over the entire surface of the one side surface 124 of the substrate 104.

The adhesive 40 is an adhesive formed of an epoxy resin as a base compound. Here, the adhesive 40 is not limited to the epoxy resin, and, for example, it is possible to use, for example, a silicone resin, a polyimide-based resin, and a urethane resin. The adhesive 40 contains fiber particles, a curing agent, or the like, in addition to the base compound.

In a process of fixing the sensor element 101 and the package 10 which will be described below, the fiber particles can control the thickness of the adhesive 40 such that the adhesive 40 is not crushed during the pressure. As the fiber particles, for example, it is possible to use aluminum, silica, silver, or the like.

The fixing portion 13 is a portion on which the adhesive 40 is applied and the sensor element 101 is fixed to the substrate 104. The side surface 124 of the substrate 104 that fixes the package 10 and the substrate 104 is a side surface on the side on which the terminal portion 109 is positioned.

In the configuration, compared to a case where the side surface on the side opposite to the side, on which the terminal portion 109 is disposed, the fixing portion 13 is disposed to be separated from the position of the semiconductor substrate 108 of the sensor element 101. As a result, it is possible to reduce the strain produced due to the thermal stress that is transmitted to the semiconductor substrate 108.

The sensor element 101 abuts on the inner bottom surface 14c of the package 10, but the sensor element may not adhere thereto. In the configuration, the heat can be transmitted through a surface with which the sensor element 101 and the package 10 are in contact, in addition to the surface of the fixed sensor element 101 which is fixed. Hence, it is possible to rapidly release a thermal gradient between the sensor element 101 and the package 10.

In the sensor element 101 is fixed such that the substantial center of the sensor element 101 is fixed to the center of the side wall 11 of the package 10 on the inner side, in the Y-axis direction In the configuration, the thermal stress produced due to a difference in coefficient of thermal expansion between the sensor element 101 and the package 10 is more evenly transmitted to the fixed sensor element 101. As a result, it is possible to reduce degradation of the temperature characteristics of the accelerometer 100.

In addition, when the sensor element 101 is fixed to the side wall 11 of the package 10 on the inner side, the adhesive 40 is crushed due to press which will be described below, and there is a possibility that the adhesive 40 leaks out from the side surface 124. Hence, in consideration of the leaking out of the adhesive 40, a recessed portion for storing the adhesive may be formed in the inner bottom surface 14c on the boundary between the inner bottom surface 14c of the package 10 and the side wall 11, or in the side wall 11.

### Method of Manufacturing Accelerometer

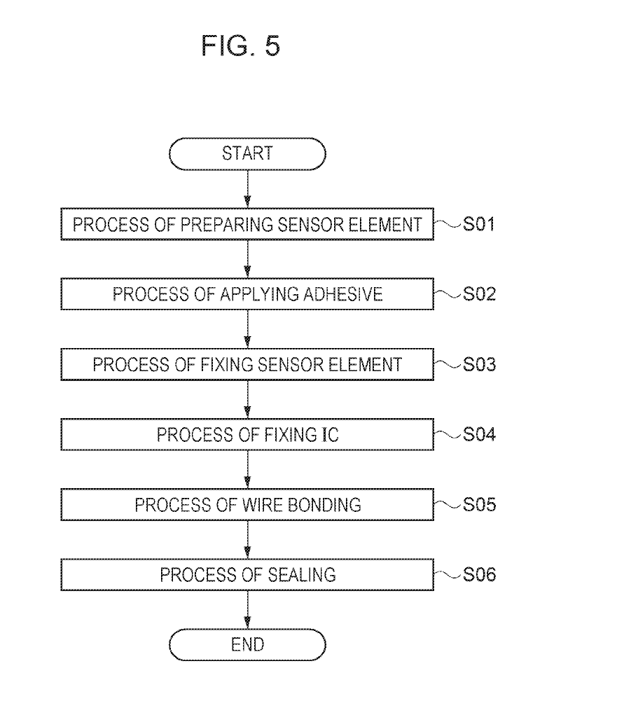

FIG. 5 is a process flowchart illustrating a method for manufacturing the accelerometer 100. As illustrated in FIG. 5, the method for manufacturing the accelerometer 100 includes: a process of preparing the sensor element 101 (Step S01), a process of applying the adhesive 40 on the side surface 124 of the substrate 104 of the sensor element 101 (Step S02), a process of fixing the side surface 124 of the substrate 104 of the sensor element 101 to the side wall 11 of the package 10 on the inner side (Step S03), a process of fixing the IC 20 on the cap 102 of the sensor element 101 (Step S04), a process of wire bonding (Step S05), and a process of sealing (Step S06).

### (1) Step S01

### Process of Preparing Sensor Element

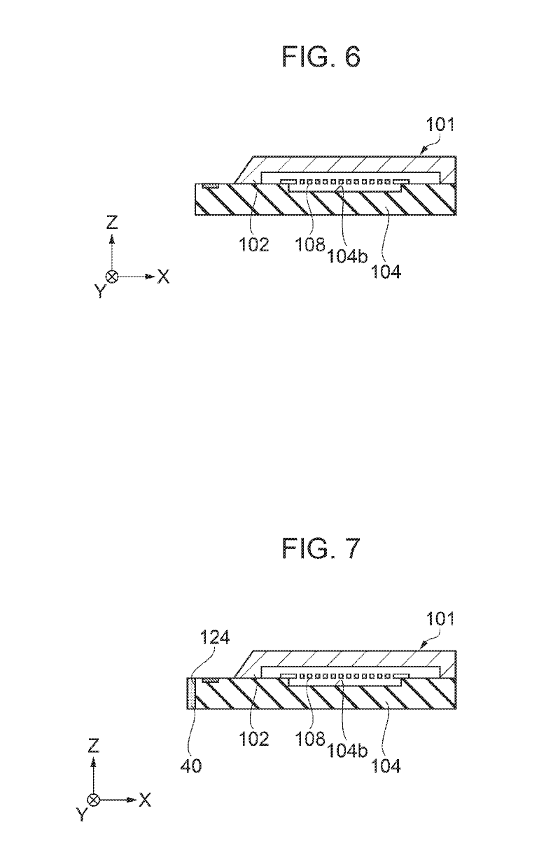

FIG. 6 is a process view schematically illustrating a process of preparing the sensor element. As illustrated in FIG. 6, the sensor element 101 that includes the substrate 104 provided with the recessed portion 104b, the semiconductor substrate 108 formed to cover the recessed portion 104b, and the cap 102 provided to cover the semiconductor substrate 108 is prepared.

### (2) Step S02

### Process of Applying Adhesive

FIG. 7 is a process view schematically illustrating a process of applying an adhesive. As illustrated in FIG. 7, the adhesive 40 made of epoxy resin as the base compound is applied on the side surface 124 of the substrate 104. For example, the application is performed by attaching the side surface 124 of the substrate 104 on an evenly applied thin film of the adhesive 40.

### (3) Step S03

### Process of Fixing Sensor Element

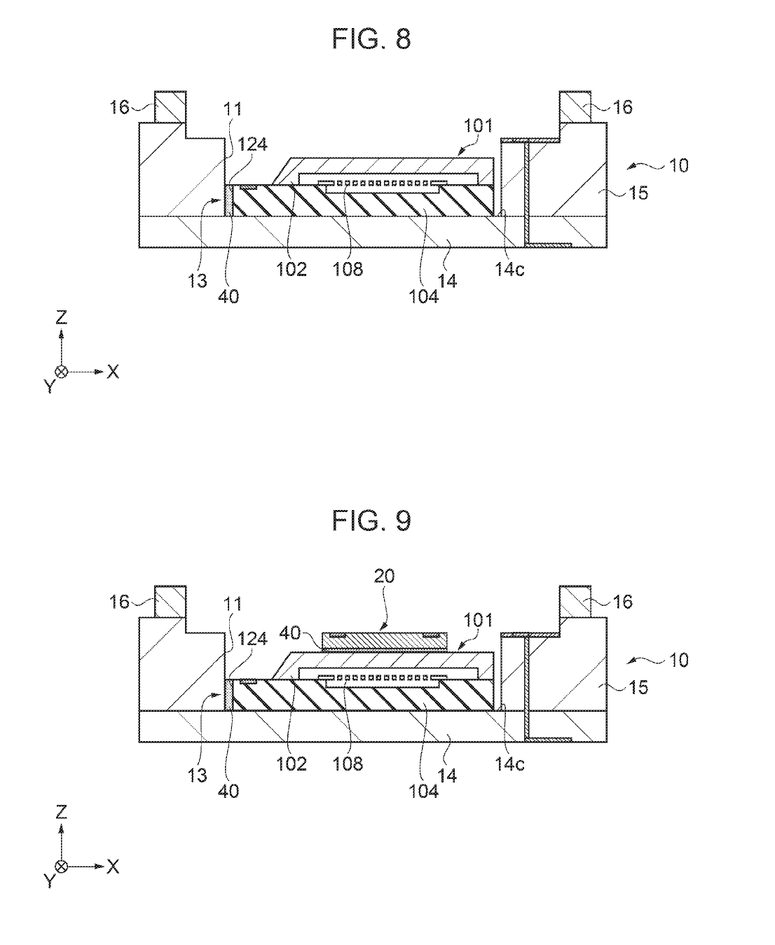

FIG. 8 is a process view schematically illustrating a process of fixing the sensor element. As illustrated in FIG. 8, the side surface 124 of the substrate 104 of the sensor element 101 is fixed to the side wall 11 of the package 10 on the inner side via the applied adhesive 40.

When the side surface 124 of the substrate 104 is fixed to the side wall 11 of the package 10 on the inner side, the substrate 104 is pressed and fixed in the −X-axial direction. In this manner, the applied adhesive 40 is crushed and it is possible to perform fixing through the entire region of the fixing portion 13 with an even thickness of about a grain size of a filler contained in the adhesive 40.

In addition, when the side surface 124 of the substrate 104 is fixed to the side wall 11 of the package 10 on the inner side, the substrate 104 is pressed and fixed in the −Z-axial direction such that the underside 104c of the substrate 104 of the sensor element 101 abuts on the inner bottom surface 14c of the package 10. In this manner, it is possible to prevent the underside 104c of the substrate 104 from floating from the inner bottom surface 14c of the package 10 during cure shrinkage of the adhesive 40 when the adhesive 40 is cured. As a result, movement of the sensor element 101 fixed to the package 10 is limited and thus it is possible to improve impact resistance.

### (4) Step S04

### Process of Fixing IC

FIG. 9 is a process view schematically illustrating a process of fixing the IC. As illustrated in FIG. 9, the adhesive 40 is applied on the upper surface of the cap 102 of the sensor element 101 by using an applicator such as a dispenser (not illustrated).

Next, the adhesive 40 applied on the upper surface of the cap 102 is brought into close contact with the IC 20, the IC 20 is pressed in the −Z-axial direction, the adhesive 40 is pressed, and the cap 102 is fixed.

### (5) Step S05

### Process of Wire Bonding

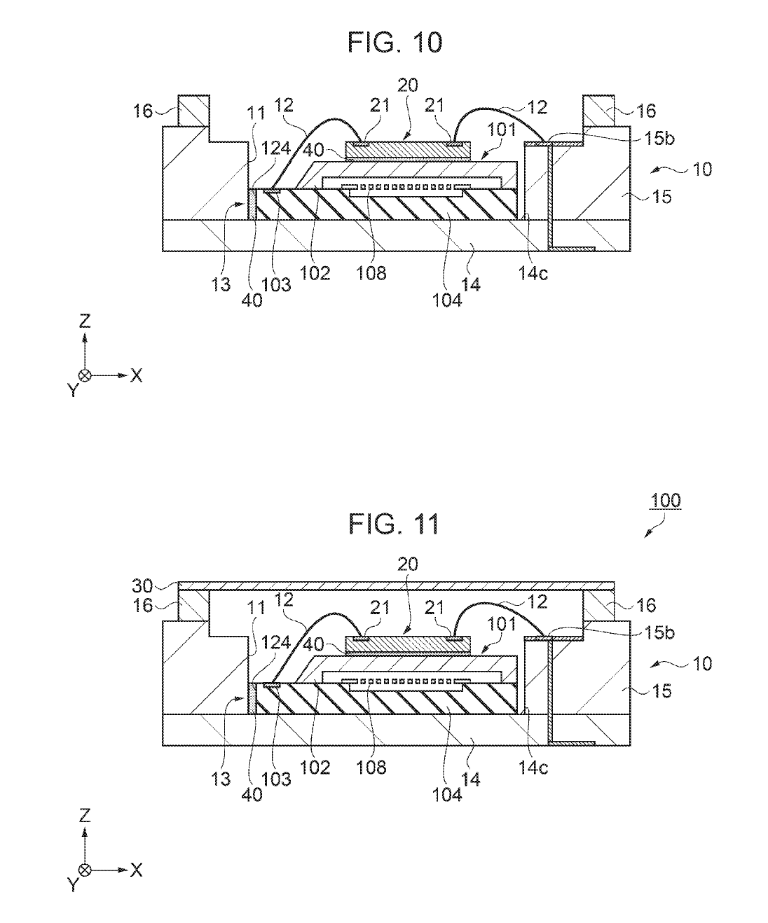

FIG. 10 is a process view schematically illustrating a process of wire bonding. As illustrated in FIG. 10, the bonding pad 21 of the IC 20 is electrically connected to the terminal electrode 103 of the substrate 104 of the sensor element 101 with the wire 12.

Next, the bonding pad 21 of the IC 20 is electrically connected to the pad 15b of the package 10 with the wire 12.

### (6) Step S06

### Process of Sealing

FIG. 11 is a process view schematically illustrating a process of sealing. As illustrated in FIG. 11, the lid 30 is welded to the seal ring 16 of the package 10 by using a seam welder.

In this manner, the accelerometer 100 is obtained.

As described above, according to the embodiment, the following effects are to be achieved.

(1) In the accelerometer 100, the side surface 124 of the sensor element 101 is fixed to the side wall 11 of the package 10 on the inner side thereof via the adhesive 40. Therefore, compared to a case where the inner bottom surface 14c of the package 10 and the underside of the sensor element 101 are fixed to each other, the side surface having the high stiffness against the bending is fixed, and thereby it is possible to reduce an occurrence of transmission, to the sensor element 101, of the strain produced due to the thermal stress produced when the sensor element 101 and the package 10 are fixed to each other with the adhesive 40. Hence, since it is not necessary to increase the package 10 in thickness in consideration of a space of a base or the like into which a material that releases the stress, is inserted, it is possible to achieve a low profile of the package 10 and it is possible to obtain an electronic device having good temperature characteristics.

(2) In the accelerometer 100, the side surface 124 of the sensor element 101 is fixed to the side wall 11 of the package 10 on the inner side thereof in the sensor element 101. Therefore, compared to a case where a plurality of side surfaces of the sensor element 101 are fixed, a range of stress which is transmitted to the sensor element 101 from the package 10 is limited. Thus, it is possible to reduce the strain produced due to the thermal stress transmitted to the sensor element 101 from the package 10, and it is possible to reduce the strain of the sensor element 101. As a result, it is possible to obtain the electronic device having good temperature characteristics.

(3) In the accelerometer 100, since the sensor element 101 abuts on the inner bottom surface 14c of the package 10, the heat can be transmitted through the inner bottom surface 14c on which the sensor element 101 and the package 10 are in contact with each other, in addition to the side surface 124 of the sensor element 101 which is fixed to the side wall 11 of the package 10 on the inner side thereof. In this manner, compared to a case where the sensor element 101 does not abut on the inner bottom surface 14c of the package 10, it is possible to rapidly release the heat gradient between the package 10 and the sensor element 101. Hence, it is possible to obtain the electronic device having good temperature characteristics.

The invention is not limited to the embodiment described above, and it is possible to perform various types of modifications or improvements on the embodiment described above. Hereinafter, modification examples will be described. Note that the same reference signs are assigned to the same configurational portions as those in the embodiment, and repeated description thereof is omitted.

### MODIFICATION EXAMPLE 1

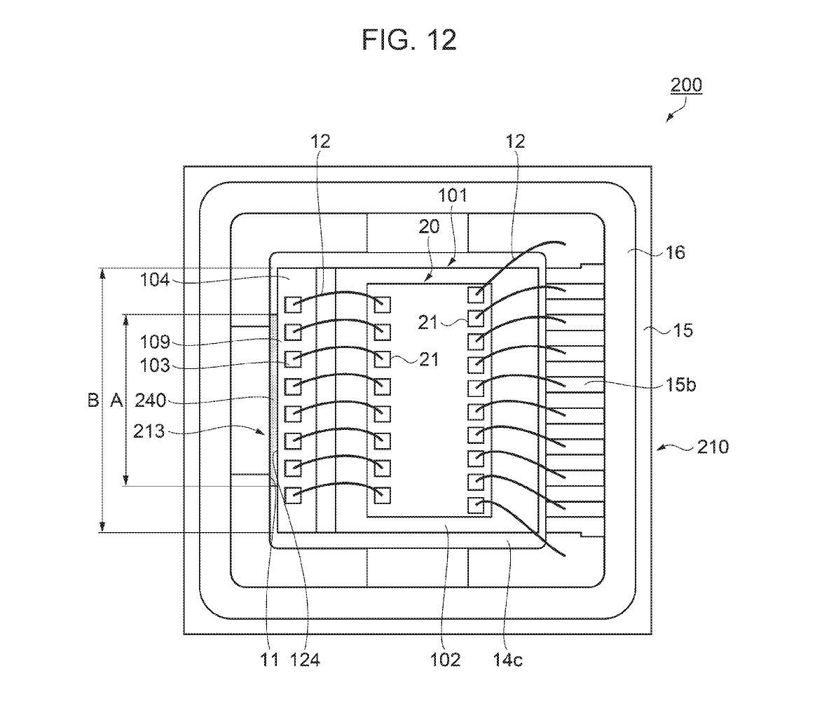

FIG. 12 is a plan view of the inside of the package. As illustrated in FIG. 12, a length A of the fixing portion 213, to which the sensor element 101 of the accelerometer 200 according to the modification example is fixed, is shorter than a length B of the side surface 124 of the sensor element 101. In other words, in the sensor element 101, a part of the one side surface 124 of the sensor element 101 is fixed to the side wall 11 of a package 210 on the inner side.

In the configuration, compared to a case where, similar to the embodiment described above, the entire range of the side surface of the sensor element 101 is fixed, it is possible to reduce the adhering area. As a result, since it is possible to reduce the thermal stress which is produced between the sensor element 101 and the package 210 and is transmitted to the sensor element 101, it is possible to obtain the electronic device having good temperature characteristics.

### MODIFICATION EXAMPLE 2

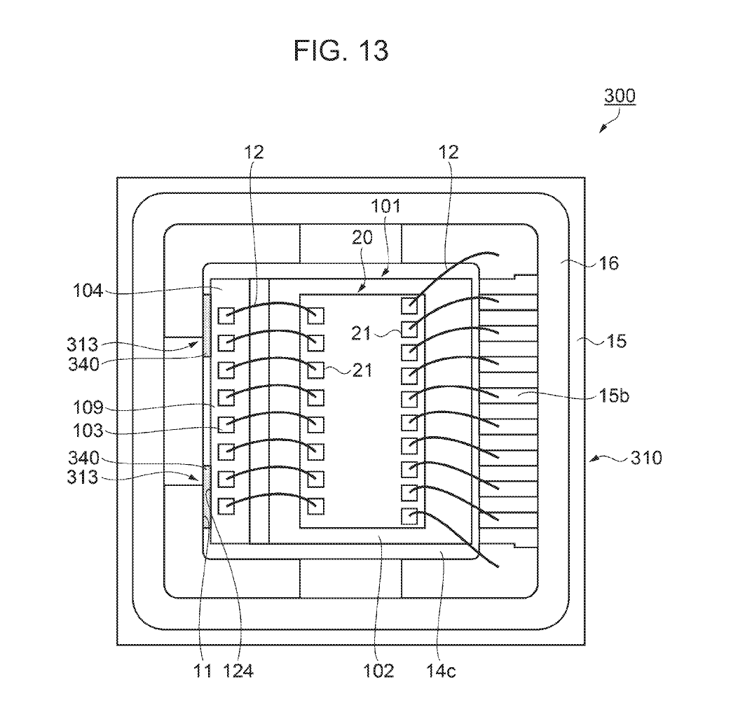

FIG. 13 is a plan view of the side wall of the package on the inner side. As illustrated in FIG. 13, the package 310 and the sensor element 101 of the accelerometer 300 may be fixed at two positions, or the number of fixed positions is not limited to two and may be three or more.

In the configuration, it is possible to more reduce the adhering area, compared to the embodiment described above. As a result, it is possible to reduce the thermal stress between the sensor element 101 and the package 310 such that it is possible to obtain the electronic device having good temperature characteristics.

### MODIFICATION EXAMPLE 3

In the embodiment described above, the configuration, in which the sensor element 101 and the IC 20 are fixed with the adhesive 40 containing the epoxy resin as the base compound, is described; however, the configuration is not limited thereto. The adhesive 40 may be an inorganic adhesive. For example, an example of the inorganic adhesive includes an adhesive containing, as the base compound, aluminum nitride, alumina, zircon, silica, silicon nitride, magnesia, and a composite thereof.

### Embodiment 2

### Configuration of Physical-Quantity Sensor

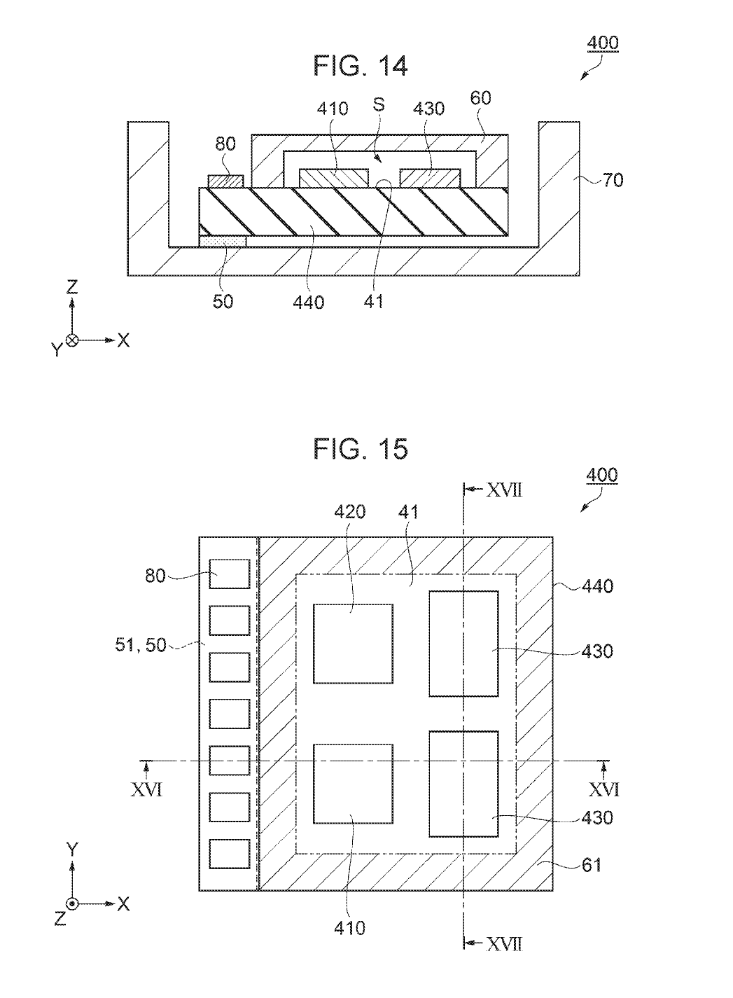

First, a schematic configuration of the physical-quantity sensor according to Embodiment 2 is described. FIG. 14 a sectional view schematically illustrating the physical-quantity sensor according to Embodiment 2. FIG. 15 is a plan view illustrating the physical-quantity sensor according to Embodiment 2. FIG. 14 corresponds to a sectional view taken along line XVI-XVI in FIG. 15. In FIG. 15, the first substrate (package 70) is omitted, and a lid member 60 is transparent.

Note that, in the figures, for convenience of description, three axes of an X axis, a Y axis, and a Z axis are represented by arrows, respectively, and a front end side of the arrow is represented by “+”, and a base end side is represented by “−”. In addition, hereinafter, a direction (first direction) parallel to the X axis is referred to as the “X-axial direction”, a direction (second direction) parallel to the Y axis orthogonal to the X axis is referred to as the “Y-axial direction”, and a direction (third direction) parallel to the Z axis orthogonal to the X axis and the Y axis is referred to as the “Z-axial direction”.

As illustrated in FIG. 14, a physical-quantity sensor 400 according to embodiment 2 includes a package 70 as a first substrate, a second substrate 440, a first sensor element 410, a second sensor element 420 (refer to FIG. 15), two third sensor elements 430, a lid member 60, and an adhesive 50. The first sensor element 410 has the detecting direction in the X-axial direction, the second sensor element 420 has the detecting direction in the Y-axial direction, and the third sensor element 430 has the detecting direction in the Z-axial direction.

The first sensor element 410, the second sensor element 420, and the two third sensor elements 430 are disposed on a main surface 41 of the second substrate 440. The lid member 60 is bonded to the main surface 41 of the second substrate 440 so as to cover the first sensor element 410, the second sensor element 420, and the two third sensor elements 430. The second substrate 440 is bonded to the package 70 as the first substrate using the adhesive 50.

### Package

The package 70 has a function of accommodating the second substrate 440 in which the first sensor element 410, the second sensor element 420, and the third sensor elements 430 are disposed, and the lid member 60 which covers the sensor elements. The package 70 has a recessed shape, and has a bottom portion disposed along an XY plane. The constituent material of the package 70 is not particularly limited; however, a material strong against external stress, such as a ceramic is preferably used.

### Adhesive

The adhesive 50 is applied between the package 70 and the second substrate 440 and has a function of bonding the package 70 and the second substrate 440 and of fixing the second substrate 440. The adhesive 50 is disposed to overlap a terminal portion 80 in a plan view. The constituent material of the adhesive 50 is not particularly limited; however, an epoxy resin or the like is used.

### Lid Member

The lid member 60 has a function of protecting the first sensor element 410, the second sensor element 420, and the third sensor elements 430. The lid member 60 is bonded to the main surface 41 of the second substrate 440, and forms a space S in cooperation with the second substrate 440, in which the first sensor element 410, the second sensor element 420, and the third sensor elements 430 are accommodated therebetween.

The lid member 60 has a plate shape, and is provided with a recessed portion in a surface facing the first sensor element 410, the second sensor element 420, and the third sensor elements 430. The recessed portion is formed to accept a shift of a movable region of the first sensor element 410, the second sensor element 420, and the third sensor elements 430. The region of an underside on an outer side from the recessed portion on the lid member 60 is bonded to the main surface 41 of the second substrate 440 described above.

It is possible for examples of a bonding method of the lid member 60 and the second substrate 440 to include a bonding method using an adhesive, an anodic bonding method, a direct bonding method, and the like. In addition, the constituent material of the lid member 60 is not particularly limited, as long as a material realizes the function as described above, and it is possible to appropriately use a silicon material, a glass material, or the like.

### Second Substrate

As illustrated in FIG. 15, the second substrate 440 has a plate shape, and has the main surface 41 which is a flat surface including the X-axial direction (first direction) and the Y-axial direction (second direction). The thickness direction of the second substrate 440 is the Z-axial direction (third direction). In FIG. 15, a region 61, in which the lid member 60 is bonded to the main surface 41 of the second substrate 440, is represented by a hatched region.

AS the constituent material of the second substrate 440, a substrate material having insulation property is preferably used, specifically, a quartz substrate, a sapphire substrate, or a glass substrate is preferably used, and, particularly, a glass material containing alkali metal ions is preferably used. In this manner, in a case where the first sensor element 410 and the lid member 60 are made of silicon as a main material, it is possible to perform the anodic bonding on the second substrate 440.

The first sensor element 410, the second sensor element 420, and the third sensor elements 430 are disposed on the main surface 41 of the second substrate 440, the first sensor element 410 and the second sensor element 420 are disposed on the −X-axial direction side of the second substrate 440, and the third sensor elements 430 are disposed on the +X-axial direction side of the second substrate 440. In addition, regarding arrangement of the first sensor element 410 and the second sensor element 420, the second sensor element 420 is disposed on the +Y-axial direction side of the second substrate, and the first sensor element 410 is disposed on the −Y-axial direction side of the second substrate.

the first sensor element 410, the second sensor element 420, and the two third sensor elements 430 are disposed on the inner side from the region 61 in which the lid member 60 is bonded to the main surface 41 of the second substrate 440. The first sensor element 410 and the second sensor element 420 are disposed to be aligned in the Y-axial direction. The two third sensor elements 430 are disposed to be aligned in the Y-axial direction.

The second substrate 440 has one side representing a region on the −X-axial direction side on the outer side from the region 61 in which the lid member 60 is bonded, and a plurality of terminal portions 80 for connecting to the outside are disposed in the Y-axial direction. The plurality of terminal portions 80 are electrically connected to the first sensor element 410, the second sensor element 420, and the two third sensor elements 430 via a wiring pattern (not illustrated) provided on the main surface 41 of the second substrate 440.

The plurality of terminal portions 80 are disposed to overlap a region 51 in which the adhesive 50 is applied in a plan view. The two third sensor elements 430 are disposed at a position farther separated from the plurality of terminal portions 80 than the first sensor element 410 and the second sensor element 420 on the +X-axial direction. In other words, the two third sensor elements 430 are disposed in the region farther separated from the one side on which the adhesive 50 is disposed than the first sensor element 410 and the second sensor element 420.

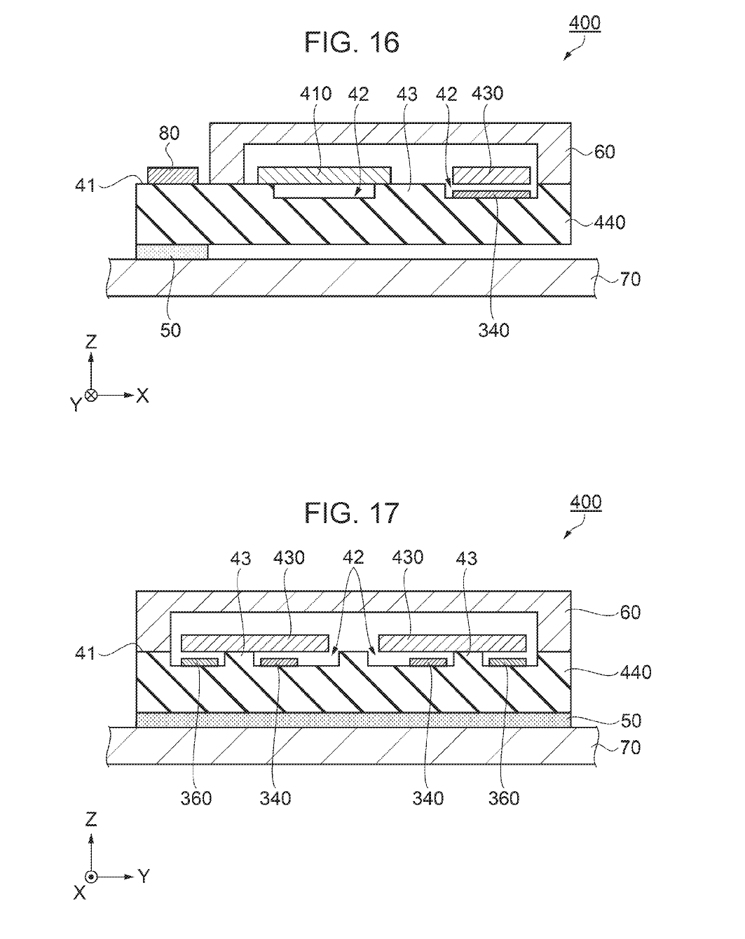

FIG. 16 is a sectional view taken along line XVI-XVI in FIG. 15. FIG. 17 is a sectional view taken along line XVII-XVII in FIG. 15. As illustrated in FIGS. 16 and 17, the second substrate 440 supports the first sensor element 410, the second sensor element 420, the third sensor elements 430, and the lid member 60. A plurality of recessed portions 42 are provided on the main surface 41 of the second substrate 440. The recessed portion 42 has a function of preventing the movable region of the first sensor element 410, the second sensor element 420, and the third sensor elements 430 from coming into contact with the second substrate 440.

In addition, the main surface 41 of the second substrate 440 is provided with a plurality of protrusions 43 that protrude from the bottom surface of the recessed portion 42. The protrusions 43 have a function of supporting the first sensor element 410, the second sensor element 420, and the third sensor elements 430. The recessed portions 42 and the protrusions 43 of the second substrate 440 can be formed through a photolithography and an etching method.

Note that, as illustrated in FIG. 17, the physical-quantity sensor 400 according to the embodiment includes two third sensor elements 430 having the detecting direction in the Z-axis direction. This is because the third sensor element 430 has low sensitivity in the X-axial direction and the Y-axial direction which are not the detecting direction of the third sensor element 430, and has high detection accuracy in the Z-axial direction as the original detecting direction. Note that the number of the third sensor elements 430 provided in the physical-quantity sensor 400 is not limited, and the physical-quantity sensor 400 may have a configuration in which one third sensor element 430 is provided.

Hereinafter, configurations of the sensor elements provided in the physical-quantity sensor 400 according to the embodiment will be described in order.

### First Sensor Element

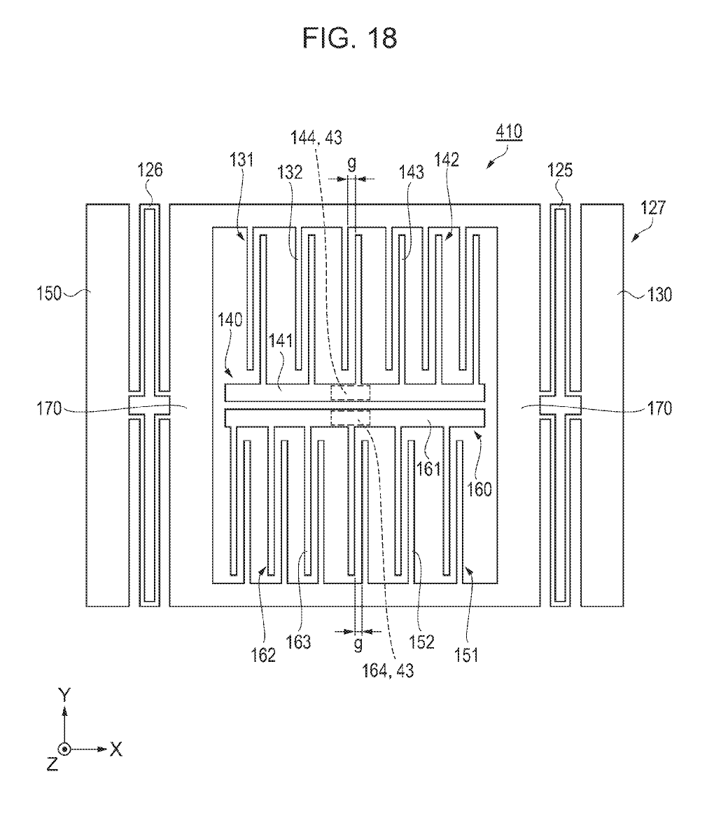

A configuration of the first sensor element 410 will be described. FIG. 18 is a plan view illustrating the first sensor element 410. The first sensor element 410 is the sensor element having the detecting direction in the X-axial direction. As illustrated in FIG. 18, the first sensor element 410 includes a first fixed-electrode-side support 140, a second fixed-electrode-side support 160, a first movable-electrode-side support 130, a second movable-electrode-side support 150, a movable mass portion 170, a pair of first elastic portions 125, and a pair of second elastic portions 126.

The first fixed-electrode-side support 140, the second fixed-electrode-side support 160, the first movable-electrode-side support 130, and the second movable-electrode-side support 150 are fixed to the main surface 41 (refer to FIG. 15) of the second substrate 440. The movable mass portion 170 is disposed to surround the first fixed-electrode-side support 140 and the second fixed-electrode-side support 160 in the plan view. The pair of first elastic portions 125, and a pair of second elastic portions 126 are connected to the first movable-electrode-side support 130, the second movable-electrode-side support 150, and the movable mass portion 170. In the embodiment, the first movable-electrode-side support 130, the second movable-electrode-side support 150, the movable mass portion 170, the pair of first elastic portions 125, and the pair of second elastic portions 126 are integrally formed and configure a movable electrode portion 127.

The first fixed-electrode-side support 140 and the second fixed-electrode-side support 160 extend in the X-axial direction and are disposed in the Y-axial direction. The first fixed-electrode-side support 140 is disposed on the +Y-axial direction side of the first sensor element 410, and the second fixed-electrode-side support 160 is disposed on the −Y-axial direction side of the first sensor element 410.

The first fixed-electrode-side support 140 includes a support 144 that is connected to the protrusion 43 of the second substrate 440, a first extending portion 141 that extends in both directions of the +X-axial direction and −X-axial direction from the support 144, and a first fixed electrode portion 142 that is connected to the first extending portion 141. The first fixed electrode portion 142 is configured of a plurality of first fixed electrode fingers 143 that have one end supported by the first extending portion 141. The plurality of first fixed electrode fingers 143 extend in the +Y-axial direction from the first extending portion 141 and is disposed to be aligned in the X-axial direction at intervals so as to configure the first fixed electrode portion 142 having a comb-teeth shape.

Similarly, the second fixed-electrode-side support 160 includes a support 164 that is connected to the protrusion 43 of the second substrate 440, a second extending portion 161 that extends in both directions of the +X-axial direction and −X-axial direction from the support 164, and a second fixed electrode portion 162 that is connected to the second extending portion 161. The second fixed electrode portion 162 is configured of a plurality of second fixed electrode fingers 163 that have one end supported by the second extending portion 161. The plurality of second fixed electrode fingers 163 extend in the −Y-axial direction from the second extending portion 161 and is disposed to be aligned in the X-axial direction at intervals so as to configure the second fixed electrode portion 162 having the comb-teeth shape.

The first movable-electrode-side support 130 and the second movable-electrode-side support 150 extend in the Y-axial direction and are disposed in the X-axial direction so as to interpose the movable mass portion 170 therebetween. The first movable-electrode-side support 130 is disposed on the +X-axial direction side of the first sensor element 410, and the second movable-electrode-side support 150 is disposed on the −X-axial direction side of the first sensor element 410. The movable mass portion 170 is a frame portion having a frame shape in a plan view and has a first movable electrode portion 131 and the second movable electrode portion 151 which are connected to the frame.

The first movable electrode portion 131 has a region facing the first fixed electrode portion 142 described above. Specifically, the first movable electrode portion 131 has one end supported by the frame portion of the movable mass portion 170 and is configured of a plurality of first movable electrode fingers 132 disposed to extend toward the inner side of the frame portion so as to mesh with the plurality of first fixed electrode fingers 143 of the first fixed electrode portion 142 described above at intervals g. The plurality of first movable electrode fingers 132 extend in the −Y-axial direction from the frame portion and is disposed to be aligned in the X-axial direction at intervals so as to configure the first movable electrode portion 131 having the comb-teeth shape.

Similarly, the second movable electrode portion 151 has a region facing the second fixed electrode portion 162 described above. Specifically, the second movable electrode portion 151 has one end supported by the frame portion of the movable mass portion 170 and is configured of a plurality of second movable electrode fingers 152 disposed to extend toward the inner side of the frame portion so as to mesh with the plurality of second fixed electrode fingers 163 of the second fixed electrode portion 162 described above at intervals g. The plurality of second movable electrode fingers 152 extend in the +Y-axial direction from the frame portion and is disposed to be aligned in the X-axial direction at intervals so as to configure the second movable electrode portion 151 having the comb-teeth shape.

The movable mass portion 170 is supported by the first movable-electrode-side support 130 described above via the two first elastic portions 125 and is supported by the second movable-electrode-side support 150 described above via the pair of second elastic portions 126.

The pair of first elastic portions 125 connect the first movable-electrode-side support 130 and the movable mass portion 170 so as to enable the movable mass portion 170 to shift in the X-axial direction. Similarly, the pair of second elastic portions 126 connect the second movable-electrode-side support 150 and the movable mass portion 170 so as to enable the movable mass portion 170 to shift in the X-axial direction More specifically, the pair of first elastic portions 125 and the pair of second elastic portions 126 are configured to be beams extending in the Y-axial direction.

Note that the shapes of the first elastic portions 125 and the second elastic portions 126 are not limited thereto, as long as the shapes enables the movable mass portion 170 to shift in the X-axial direction; and, for example, the elastic portion may be configured of three or more beams and two or more connecting portions that connect the beams. In addition, the pair of first elastic portions 125 may have a shape that extends in the −X-axial direction while meandering in the Y-axial direction to repeat approaches to and separations from each other from the end portion of the first movable-electrode-side support 130 on the −X-axial direction side, and the pair of second elastic portions 126 may have a shape that extends in the +X-axial direction while meandering in the Y-axial direction to repeat approaches to and separations from each other from the end portion of the second movable-electrode-side support 150 on the +X-axial direction side.

The constituent materials of the first fixed-electrode-side support 140, the second fixed-electrode-side support 160, and the movable mass portion 170, respectively, are not particularly limited, and, for example, preferably, a silicon material (monocrystalline silicon, polysilicon, or the like) to which the conductivity is applied by being doped with impurities such as phosphorus or boron.

Subsequently, an operation of the first sensor element 410 will be described. When the first sensor element 410 receives the acceleration in the X-axial direction as the detecting direction, the movable mass portion 170 shifts in the X-axial direction in response to elastic deformation of the first elastic portions 125 and the second elastic portions 126. Then, both of a distance between the first fixed electrode fingers 143 of the first fixed electrode portion 142 and the first movable electrode fingers 132 of the first movable electrode portion 131 and a distance between the second fixed electrode fingers 163 of the second fixed electrode portion 162 and the second movable electrode fingers 152 of the second movable electrode portion 151 change. Since the capacitances between the portions change in response to the changes in the distances, it is possible to detect the magnitude of the acceleration received by the first sensor element 410 based on the change in the capacitance.

In the embodiment, since the first movable electrode fingers 132 are disposed on the −X-axial direction side of the first fixed electrode fingers 143, and the second movable electrode fingers 152 are disposed on the +X-axial direction side of the second fixed electrode fingers 163, a distance between the first fixed electrode fingers 143 and the first movable electrode fingers 132 and the distance between the second fixed electrode fingers 163 and the second movable electrode fingers 152 have a relationship in which one distance decreases when the other distance increases. Therefore, the capacitance between the first fixed electrode fingers 143 and the first movable electrode fingers 132 and the capacitance between the second fixed electrode fingers 163 and the second movable electrode fingers 152 also have a relationship in which one capacitance decreases when the other capacitance increases.

Hence, a signal is calculated through a differential operation, based on the capacitance between the first fixed electrode fingers 143 of the first fixed electrode portion 142 and the first movable electrode fingers 132 of the first movable electrode portion 131 and a signal is calculated through the differential operation, based on the capacitance between the second fixed electrode fingers 163 of the second fixed electrode portion 162 and the second movable electrode fingers 152 of the second movable electrode portion 151. In this manner, while it is possible to reduce noise by removing a signal component in response to the shift of the movable mass portion 170 in directions other than the detecting direction, it is possible to output a signal corresponding to the acceleration received by the first sensor element 410.

### Second Sensor Element

The second sensor element 420 is the sensor element having the detecting direction in the Y-axial direction. Since the first sensor element 410 and the second sensor element 420 have the same configuration, and the first sensor element 410 is the same as the second sensor element 420 when the first sensor element 410 in FIG. 18 rotates around the Z axis by 90°, the description of the configuration of the second sensor elements 420 is omitted.

### Third Sensor Element

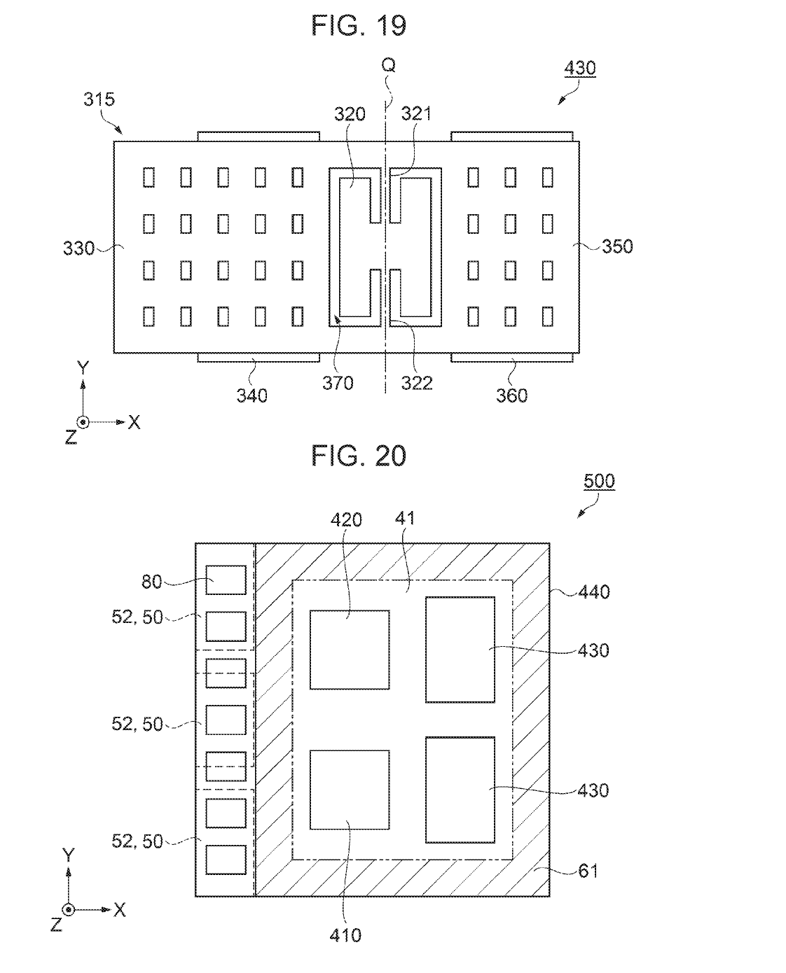

FIG. 19 is a plan view illustrating the third sensor element. The third sensor element 430 is the sensor element having the detecting direction in the Z-axial direction. As illustrated in FIG. 19, the third sensor element 430 includes a movable member 315, a first fixed electrode portion 340, and a second fixed electrode portion 360. The first fixed electrode portion 340 and the second fixed electrode portion 360 are provided on the bottom surface of the recessed portion 42 of the second substrate 440 so as to have at least a part thereof which overlaps the movable member 315 in the plan view (refer to FIG. 17).

The movable member 315 includes a first movable electrode portion 330, a second movable electrode portion 350, a first elastic portion 321, a second elastic portion 322, and a support 320 that is connected to the protrusion (refer to FIG. 17) of the second substrate 440. The movable member 315 is formed to have a flat plate shape, is provided with an opening 370 formed to penetrate the movable member in the thickness direction (Z-axial direction) at a position along a support axis Q on the XY plane, and includes the first elastic portion 321, the second elastic portion 322, and the support 320 on the inner side of the opening 370.

The first elastic portion 321 and the second elastic portion 322 are formed along the support axis Q as an imaginary line in the Y-axial direction. The first elastic portion 321 extends in the +Y-axial direction from the support 320, and the second elastic portion 322 extends in the −Y-axial direction from the support 320. The support 320 is provided to be interposed between the first elastic portion 321 and the second elastic portion 322. The support 320 is formed along the support axis Q so as to have line symmetry.

The support 320 is fixed to and is supported by the protrusion 43 of the second substrate 440. Since the movable member 315 is provided to face the first fixed electrode portion 340 and the second fixed electrode portion 360 in the Z-axial direction at intervals, and the first elastic portion 321 and the second elastic portion 322 can twist in a rotating direction of rotating around the support axis Q, the movable member 315 is able to rotate so as to seesaw around the support axis Q.

The movable member 315 includes the first movable electrode portion 330 in a region in the −X-axial direction from the support axis Q, and the second movable electrode portion 350 in a region in the +X-axial direction from the support axis Q, in a plan view, and the first movable electrode portion 330 and the second movable electrode portion 350 are asymmetrically provided with the support axis Q as a reference. The first fixed electrode portion 340 is provided in the recessed portion 42 (refer to FIG. 17) of the second substrate 440 so as to overlap the first movable electrode portion 330 of the movable member 315 in the plan view, and the second fixed electrode portion 360 is provided in the recessed portion 42 of the second substrate 440 so as to overlap the second movable electrode portion 350 of the movable member 315 in the plan view.

Subsequently, an operation of the third sensor element 430 will be described. In a case where the acceleration in the Z-axial direction as the detecting direction is applied to the third sensor element 430 of the embodiment, the rotation moment is produced in the first movable electrode portion 330 and the second movable electrode portion 350 of the movable member 315 around the support axis Q in response to shifts of the first elastic portion 321 and the second elastic portion 322, and the movable member 315 tilts in response to the rotation moment. Since the first movable electrode portion 330 is asymmetrical to the second movable electrode portion 350, a direction of the tilt of the movable member 315, which is obtained when the rotation moment is produced, is defined.

When the movable member 315 tilts, both of a distance between the first fixed electrode portion 340 provided on the bottom surface in the recessed portion 42 and the first movable electrode portion 330 in the Z-axial direction and a distance between the second fixed electrode portion 360 and the second movable electrode portion 350 in the Z-axial direction change. Since the capacitances between the portions change in response to the changes in the distances, it is possible to detect the magnitude of the acceleration received by the third sensor element 430 based on the change in the capacitances.

In the embodiment, the distance between the first fixed electrode portion 340 and the first movable electrode portion 330 and the distance between the second fixed electrode portion 360 and the second movable electrode portion 350 have a relationship in which one distance decreases when the other distance increases. Therefore, the capacitance between the first fixed electrode portion 340 and the first movable electrode portion 330 and the distance between the second fixed electrode portion 360 and the second movable electrode portion 350 also have a relationship in which one capacitance decreases when the other capacitance increases.

Hence, a signal is calculated through a differential operation, based on the capacitance between the first fixed electrode portion 340 and the first movable electrode portion 330 and a signal is calculated through the differential operation, based on the capacitance between the second fixed electrode portion 360 and the second movable electrode portion 350. In this manner, while it is possible to reduce noise by removing a signal component in response to the shift of the movable member 315 in directions other than the Z-axial direction as the detecting direction, it is possible to output a signal corresponding to the acceleration received by the first sensor element 410.

Here, a case where the adhesive 50 is applied to the entire region (entire surface facing the package 70) of the second substrate 440 in the physical-quantity sensor 400 illustrated in FIG. 14 is assumed. In a case of such a configuration, when the package 70 is deformed due to the application of the external stress or the like, the second substrate 440 is likely to be deformed via the adhesive 50. In addition, when the ambient temperature of the physical-quantity sensor 400 changes, the second substrate 440 is likely to be deformed due to the difference in coefficient of thermal expansion between the second substrate 440 and the adhesive 50. The second substrate 440 is deformed to have a convex or concave shape, that is, in the thickness direction of the second substrate 440.

When the second substrate 440 is deformed, both of the distance between the first fixed electrode fingers 143 and the first movable electrode fingers 132 and the distance between the second fixed electrode fingers 163 and the second movable electrode fingers 152 in the first sensor element 410 and the second sensor element 420 change. Thus, the accelerations in the X-axial direction and the Y-axial direction are detected with low accuracy.

In addition, since the distance between the first fixed electrode portion 340 and the first movable electrode portion 330 and the distance between the second fixed electrode portion 360 and the second movable electrode portion 350 in the third sensor element 430 change, the acceleration in the Z-axial direction is detected with low accuracy. Since the first fixed electrode portion 340 and the second fixed electrode portion 360 are formed on the bottom surface of the recessed portion 42 of the second substrate 440 in the third sensor element 430, the deformation of the second substrate 440 is likely to have an effect on the third sensor element, compared to the first sensor element 410 and the second sensor element 420.

In the physical-quantity sensor according to JP-A-2006-250702, the substrate is provided with a counterbore such that an area, on which the adhesive is applied between the package and the substrate, is reduced, and thereby deformation of the substrate due to the external stress or the difference in coefficient of thermal expansion is reduced such that reduction in the degradation of detection accuracy due to the deformation of the substrate is achieved. However, since the outer periphery (four sides), two sides, or four corners of the substrate is fixed to the package with the adhesive, the substrate is likely to be deformed to a certain degree between the opposing sides or the opposing angles due to the external stress or the difference in coefficient of thermal expansion.

In addition, in the physical-quantity sensor disclosed in JP-A-2006-250702, the fixed electrode portions and the supports, which support the movable electrode portion of the sensor element, are positioned to overlap each other in a plane in a region in which the adhesive, which fixes the substrate to the package, is applied. Therefore, in a case where the package is deformed due to the external stress or in a case where the ambient temperature changes and thus the glass substrate is deformed due to the difference in coefficient of thermal expansion between the substrate and the adhesive, a region of the glass substrate, to which the fixed electrode portion and the support are fixed, is also deformed. Thus, the sensor element performs detection with low accuracy.

In this respect, in the physical-quantity sensor 400 according to the embodiment, the adhesive 50 is disposed to overlap a plurality of terminal portions 80 in the plan view. In other words, the region 51, in which the adhesive 50 is applied, is the region that does not overlap the first sensor element 410, the second sensor element 420, and the third sensor element 430, in the plan view, which are disposed on the second substrate 440, and is positioned on one side separated from the third sensor element 430 in the −X-axial direction on the second substrate 440.

Therefore, in a case where the package 70 is deformed due to the external stress, the deformation of the package 70 is difficult to be transmitted to the region of the second substrate 440 in which the first sensor element 410, the second sensor element 420, and the third sensor elements 430 are disposed, even when the deformation is transmitted to the second substrate 440 via the adhesive 50. In addition, even in a case where the second substrate 440 is deformed due to the difference in coefficient of thermal expansion between the adhesive 50 ad the second substrate 440 owing to the change in the ambient temperature, the region, in which the first sensor element 410, the second sensor element 420, and the third sensor elements 430 are disposed, is difficult to be deformed even when the region 51 of the second substrate 440, in which the adhesive 50 is applied, is deformed.

Since, in the first sensor element 410 and the second sensor element 420, the first fixed electrode fingers 143 of the first fixed electrode portion 142 and the second fixed electrode fingers 163 of the second fixed electrode portion 162 and the first movable-electrode-side support 130 and the second movable-electrode-side support 150, which support the movable electrode portion 127, do not overlap the region 51, in which the adhesive 50 is applied, in the plan view, it is difficult to receive an effect of the deformation of the second substrate 440. In addition, since, in the third sensor element 430, the first fixed electrode portion 340 and the second fixed electrode portion 360 and the support 320 that supports the movable member 315 including the first movable electrode portion 330 and the second movable electrode portion 350 do not overlap the region 51, in which the adhesive 50 is applied, in the plan view, it is difficult to receive an effect of the deformation of the second substrate 440.

Further, since the third sensor elements 430, which are likely to receive the effect of the deformation of the second substrate 440, compared to the first sensor element 410 and the second sensor element 420, are disposed to be farther separated from the region 51, in which the adhesive is disposed, than the first sensor element 410 and the second sensor element 420, the deformation of the second substrate 440 is unlikely to be transmitted to the two third sensor elements 430. As a result, it is possible for the physical-quantity sensor 400 according to the embodiment to detect the physical quantities with higher accuracy.

As described above, in the physical-quantity sensor 400 according to the embodiment, it is possible to achieve the following effects.

(1) In the physical-quantity sensor 400 according to the embodiment, the adhesive 50 that fixes the second substrate 440 on the package 70 is provided on the one side of the second substrate 440 on the outer peripheral portion. Therefore, in a case where the deformation of the package 70 due to the external stress is transmitted to the second substrate 440 via the adhesive 50, or in a case where the second substrate 440 is deformed due to the difference in coefficient of thermal expansion between the adhesive 50 and the second substrate 440, the second substrate 440 is less deformed in regions other than the one side of the outer peripheral portion. The adhesive 50 is disposed so as not to overlap the first sensor element 410, the second sensor element 420, and the third sensor elements 430 which are disposed on the second substrate 440 in the plan view. Therefore, even when the second substrate 440 is deformed, the deformation is difficult to have an effect on the first fixed electrode fingers 143, the second fixed electrode fingers 163, the first movable-electrode-side supports 130, and the second movable-electrode-side supports 150 of the first sensor element 410 and the second sensor element 420, and the first fixed electrode portion 340, the second fixed electrode portion 360, and the support 320 of the third sensor element 430. Hence, it is possible to provide the physical-quantity sensor 400 that is capable of detecting the physical quantity with higher accuracy with respect to the external stress or the change in the ambient temperature.

(2) In the physical-quantity sensor 400 according to the embodiment, the terminal portions 80 provided on the one side of the second substrate 440 are disposed to overlap the adhesive 50 in the plan view. Since the terminal portions 80 are not the portion that have a significant effect on the accuracy of the measurement of the first sensor element 410, the second sensor element 420, and the third sensor elements 430, there is little effect on the accuracy of the measurement of the first sensor element 410, the second sensor element 420, and the third sensor elements 430, even when the first side of the second substrate 440, which overlaps the adhesive 50, is deformed. In addition, the terminal portions 80 are disposed on the one side of the second substrate 440 on the outer peripheral portion, and thereby it is possible to disposed the first fixed electrode fingers 143, the second fixed electrode fingers 163, the first movable-electrode-side supports 130, and the second movable-electrode-side supports 150 of the first sensor element 410 and the second sensor element 420, and the first fixed electrode portion 340, the second fixed electrode portion 360, and the support 320 of the third sensor element 430 at positions separated from the region 51 in which the adhesive 50 is applied. In this manner, it is possible to increase the accuracy of the physical-quantity sensor 400.

(3) The physical-quantity sensor 400 according to the embodiment includes the first sensor elements 410, the second sensor element 420, and the third sensor elements 430 that detect three directions different from each other, in which the third sensor element 430, which detects the Z-axial direction intersecting with the main surface 41 of the second substrate 440, is disposed in the region farther separated from the one side of the second substrate 440 than the first sensor element 410 having the detecting direction in the X-axial direction and the second sensor element 420 having the detecting direction in the Y-axial directions which are parallel to the main surface 41 of the second substrate 440. The third sensor element 430 has the detecting direction in the Z-axial direction intersecting with the main surface 41 (recessed portion 42) of the second substrate 440 to which the first fixed electrode portion 340 and the second fixed electrode portion 360 are fixed, that is, the thickness direction of the second substrate 440. In the case where the deformation of the package 70 due to the external stress is transmitted to the second substrate 440 via the adhesive 50, or in a case where the second substrate 440 is deformed due to the difference in coefficient of thermal expansion between the adhesive 50 and the second substrate 440, the second substrate 440 is deformed in the thickness direction. Therefore, the third sensor elements 430 having the detecting direction in the thickness direction of the second substrate 440 are likely to have degradation in the accuracy of the sensor due to the deformation of the second substrate 440, compared to the first sensor element 410 and the second sensor element 420 that have the detecting directions in the directions along the main surface 41 of the second substrate 440. The third sensor elements 430 are farther separated from the one side of the second substrate 440 on which the adhesive 50 is disposed, than the first sensor element 410 and the second sensor element 420, and thereby the degradation in the accuracy of the third sensor elements 430 due to the deformation of the second substrate 440 is reduced. As a result, it is possible to increase the accuracy of the physical-quantity sensor 400.

### Embodiment 3

Next, a physical-quantity sensor 500 according to Embodiment 3 will be described. FIG. 20 is a plan view illustrating the physical-quantity sensor according to Embodiment 3. The physical-quantity sensor 500 according to Embodiment 3 has a configuration which is different from that of Embodiment 2 in that the adhesive 50 is not continuously applied in the Y-axial direction but is disconnected at least at two positions. The configuration is the same as that of Embodiment 2 except for this described above. Note that the same reference signs are assigned to the same configurational portions as those in Embodiment 2, and repeated description thereof is omitted.

As illustrated in FIG. 20, similar to the physical-quantity sensor 400 according to Embodiment 2, the physical-quantity sensor 500 according to Embodiment 3 includes the first sensor element 410, the second sensor element 420, the two third sensor elements 430, the second substrate 440, the lid member 60 (refer to FIG. 14), the package 70 (refer to FIG. 14), and an adhesive 50 (refer to FIG. 14).

In the physical-quantity sensor 500 according to Embodiment 3, the adhesive 50 is applied, in the second substrate 440, on the same one side as in the physical-quantity sensor 400 according to Embodiment 2; however, a region 52, in which the adhesive 50 is applied, is disconnected at least at two positions. Hence, in the physical-quantity sensor 500 according to Embodiment 3, a total area of the region 52, in which the adhesive 50 is applied, is smaller than the region 51 in which the adhesive 50 is applied in embodiment 2.

Therefore, in a case where the package 70 is deformed due to the external stress, an area, in which the deformation of the package 70 is transmitted to the second substrate 440 via the adhesive 50, is reduced. In addition, the adhesive 50 is disconnected and thereby the transmission of the deformation is reduced. Thus, it is possible to more reduce the deformation of the second substrate 440 than in Embodiment 2. In addition, even in a case where the second substrate 440 is deformed due to the difference in coefficient of thermal expansion between the adhesive 50 and the second substrate 440 owing to the change in the ambient temperature, an area of the application of the adhesive 50 is reduced and is disconnected. Thus, it is possible to more reduce the deformation of the second substrate 440 than in Embodiment 2.

According to the physical-quantity sensor 500 of Embodiment 3, the same effects as those of Embodiment 2 are achieved. Further, the area of application of the adhesive 50 is reduced, compared to Embodiment 2. Therefore, in the case where the deformation of the package 70 due to the external stress is transmitted to the second substrate 440 via the adhesive 50, or in the case where the second substrate 440 is deformed due to the difference in coefficient of thermal expansion between the adhesive 50 and the second substrate 440, the deformation of the second substrate 440 is difficult to be transmitted to the first sensor element 410, the second sensor element 420, and the third sensor elements 430. Hence, it is possible to provide the physical-quantity sensor 500 that is capable of detecting the physical quantity with higher accuracy with respect to the external stress or the change in the ambient temperature.

### Embodiment 4

### Electronic Apparatus

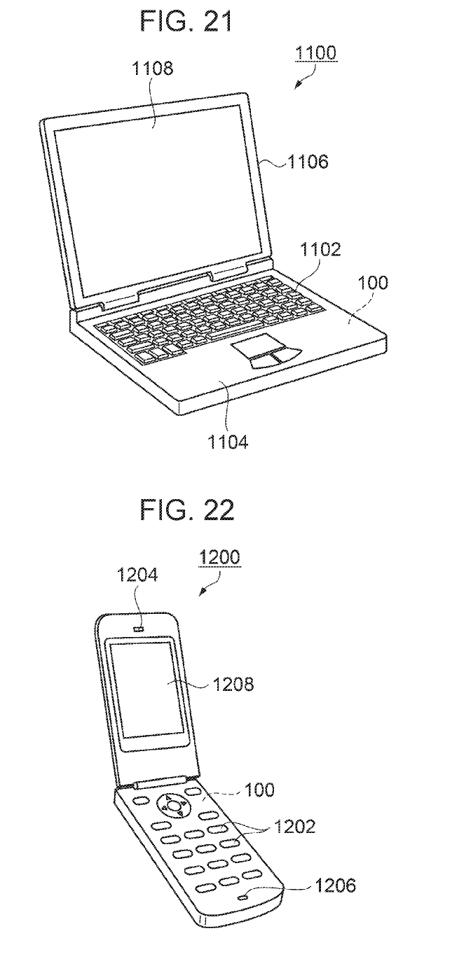

Next, an electronic apparatus according to Embodiment 4 will be described with reference to FIGS. 21, 22 and 23. The electronic apparatus according to Embodiment 4 includes one of the accelerometer 100, 200, or 300 or the physical-quantity sensor 400 or 500 of the embodiment described above. Note that, in the following description, a configuration, to which the accelerometer 100 is applied, is provided.

FIG. 21 schematically illustrates a mobile-type (or notebook-type) personal computer as an example of the electronic apparatus according to Embodiment 4. As illustrated in FIG. 21, a personal computer 1100 includes a main body 1104 provided with a keyboard 1102 and a display unit 1106 provided with the display portion 1108. The display unit 1106 is rotatably supported by the main body 1104 via a hinge structure. The personal computer 1100 has the built-in accelerometer 100 of the embodiments described above.

FIG. 22 schematically illustrates a configuration of a mobile phone (also including a PHS) as an example of the electronic apparatus according to Embodiment 4. As illustrated in FIG. 22, a mobile phone 1200 includes a plurality of operating buttons 1202, an earpiece 1204, and a mouthpiece 1206, in which a display portion 1208 is disposed between the operating buttons 1202 and the earpiece 1204. The mobile phone 1200 has the built-in accelerometer 100 of the embodiments described above.

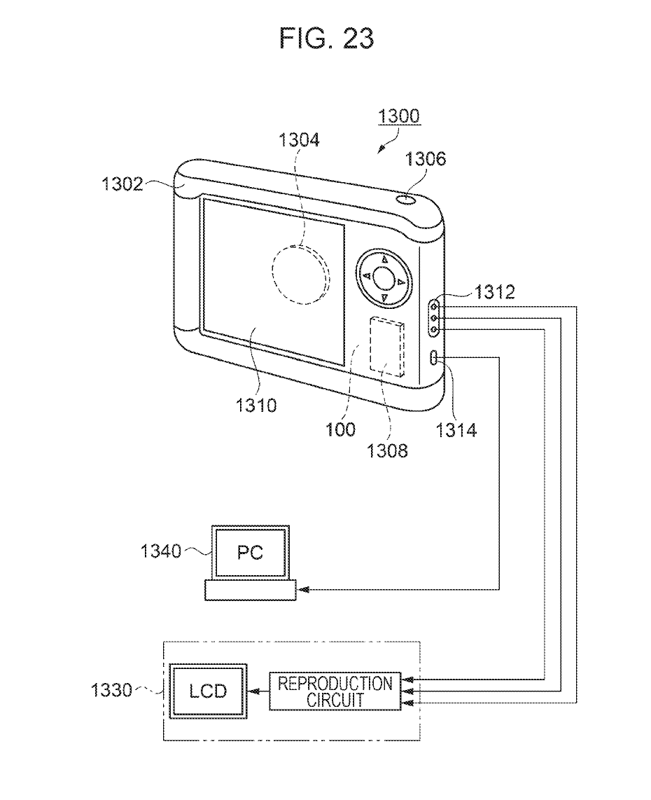

FIG. 23 schematically illustrates a configuration of a digital still camera as an example of the electronic apparatus according to Embodiment 4. Note that FIG. 23 illustrates connection to an external apparatus in a simplified manner. Here, a common camera causes an analog photography film to be photosensitive to an optical image of a subject. In contrast, a digital still camera 1300 performs photoelectric conversion of an optical image of a subject, using an imaging device such as a charge coupled device (CCD), and generates an imaging signal (image signal).

As illustrated in FIG. 23, a display portion 1310 is provided on the rear surface of a case (body) 1302 in the digital still camera 1300, and has a configuration in which a display is performed in response to an imaging signal by the CCD. The display portion 1310 functions as a finder that displays the subject as an electronic image. In addition, a light receiving unit 1304 that includes a light receiving lens (imaging optical system), a CCD, or the like is provided on the front surface side (rear surface side in FIG. 23) of the case 1302.

When a photographer checks an image of a subject displayed on the display portion 1310, and presses a shutter button 1306, an imaging signal of the CCD at the time point is transmitted to and stored in a memory 1308. In addition, in the digital still camera 1300, a video signal output terminal 1312 and an input/output terminal 1314 for data communication are provided on the side surface of the case 1302.

A television monitor 1330 is connected to the video signal output terminal 1312, and a personal computer 1340 is connected to the input/output terminal 1314 for data communication, as necessary. Further, the imaging signal stored in the memory 1308 is configured to be output to the television monitor 1330 or to the personal computer 1340 by a predetermined operation. The digital still camera 1300 has the built-in accelerometer 100 of the embodiments described above.

In addition to the applications of the accelerometers 100, 200, and 300 and the physical-quantity sensors 400 and 500 to the personal computer 1100, the mobile phone 1200, and the digital still camera 1300 according to Embodiment 4, the accelerometer and the physical-quantity sensor can be applied to an electronic apparatus, such as an ink jet discharge apparatus (for example, an ink jet printer), a laptop personal computer, a TV, a video camera, a video tape recorder, a car navigation device, a pager, an electronic organizer (including a communicating function), an electronic dictionary, a calculator, an electronic game device, a word processor, a workstation, a TV phone, a security television monitor, electronic binoculars, a POS terminal, a medical apparatus (for example, an electronic thermometer, a sphygmomanometer, a blood glucose meter, an electrocardiogram measuring device, an ultrasonic diagnostic apparatus, or an electronic endoscope), a fishfinder, various measurement apparatuses, meters (for example, meters on a vehicle, an aircraft, or a ship), or a flight simulator.

### Embodiment 5

### Moving Object

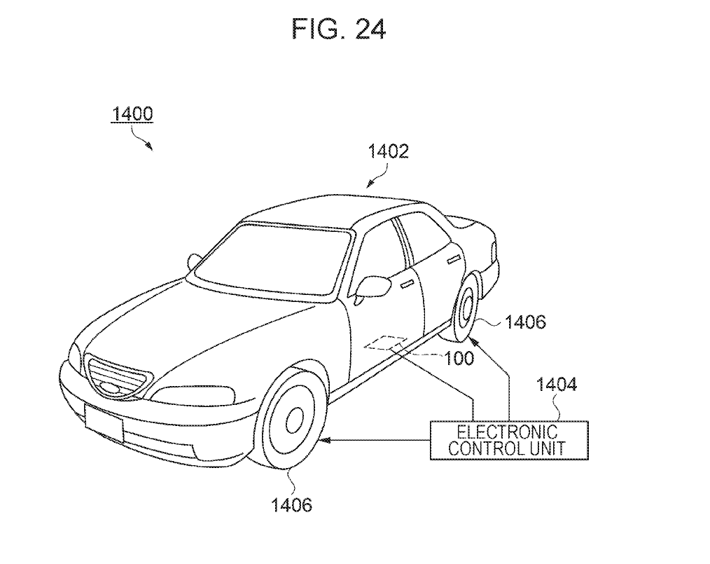

Next, a moving object according to Embodiment 5 is described with reference to FIG. 24. The moving object according to Embodiment 5 includes one of the accelerometer 100, 200, or 300 or the physical-quantity sensor 400 or 500 of the embodiment described above. Note that, in the following description, a configuration, to which the accelerometer 100 is applied, is provided. FIG. 24 is a perspective view schematically illustrating the moving object according to Embodiment 5.

FIG. 24 schematically illustrates a configuration of an automobile as an example of the moving object according to Embodiment 5. As illustrated in FIG. 24, an automobile 1400 includes a vehicle body 1402 and tires 1406, and an electronic control unit 1404 that controls the tires 1406 or the like is installed on a vehicle body 1402. The electronic control unit 1404 has the built-in accelerometer 100 of the embodiments described above.

In addition, note that the accelerometers 100, 200, and 300 and the physical-quantity sensors 400 and 500 according to the embodiments described above can be applied to an electronic control unit (ECU), such as keyless entry, an immobilizer, a car navigation system, a car air conditioner, an anti-lock brake system (ABS), an airbag, a tire pressure monitoring system (TPMS), an engine control, a battery monitor of a hybrid car or an electric car, or a vehicle body posture control system.

The embodiment described above represents only an aspect of the invention, and it is possible to arbitrarily modify and apply the embodiment within a range of the technical idea of the invention. Modification examples thereof are considered as follows.

The application of the accelerometer 100 according to Embodiment 1 is not limited to the automobile 1400, and can be applied to a posture detecting sensor of the moving object including a self-propelled robot, a self-propelled transport device, a train, a ship, an airplane, an artificial satellite, or the like. In any case, the effects described in the embodiments described above are reflected such that it is possible to provide the moving object that exhibits good performance.

In addition, the accelerometer 100 is not limited to being used in the physical-quantity sensors described above, and may be a vibrator including MEMS vibrating pieces having a comb-teeth shape.

In addition, the physical-quantity sensor 400 according to Embodiment 2 and the physical-quantity sensor 500 according to Embodiment 3 are compound sensors having four sensor elements of the first sensor element 410, the second sensor element 420, and the two third sensor elements 430; however, the invention is not limited to the embodiments described above. For example, regarding the sensor element, a compound sensor may have three or less sensor elements of the four sensor elements, or the physical quantity sensor may have one of the four sensor elements. Even in the configurations, as long as the adhesive 50 is disposed such that at least the fixed electrode portion of the sensor element does not overlap the support that supports the movable electrode portion in a plane, the same effects as those in the embodiments described are achieved.

The entire disclosures of Japanese Patent Application Nos. 2016-004165, filed Jan. 13, 2016 and 2016-014063, filed Jan. 28, 2016 are expressly incorporated by reference herein.

What is claimed is:

1. An electronic device comprising:
a package; and
a functional element,
wherein a side surface of the functional element is fixed to a side wall of the package on an inner side thereof via an adhesive.

2. The electronic device according to claim 1,
wherein the functional element is fixed to the side wall to which one side surface of the functional element is fixed.

3. The electronic device according to claim 2,
wherein the functional element is fixed to the side wall to which a part of the one side surface of the functional element is fixed.

4. The electronic device according to claim 1,
wherein the functional element abuts on an inner bottom surface of the package.

5. The electronic device according to claim 4,
wherein the package is formed of a material containing a ceramic.

6. The electronic device according to claim 5,
wherein the functional element has a substrate and the substrate is formed of a material containing borosilicate glass.

7. The electronic device according to claim 6,
wherein a base compound of the adhesive is formed of a resin-based material.

8. The electronic device according to claim 6,
wherein a base compound of the adhesive is formed of an inorganic material.

9. A method for manufacturing an electronic device comprising:
applying an adhesive on a side surface of a functional element;
fixing the side surface of the functional element to a side surface of a package on an inner side thereof;
curing the adhesive;
fixing an IC to the functional element;
electrically connecting the functional element and the IC;
electrically connecting the package and the IC; and
mounting and sealing a lid member on the package.

10. A physical-quantity sensor comprising:
a first substrate;
a second substrate fixed on the first substrate via the adhesive; and
a sensor element disposed on the second substrate,
wherein the sensor element is provided with a fixed electrode portion fixed to the second substrate, and a support that fixes a movable electrode portion to be movable and is fixed to the second substrate, and
wherein the adhesive is disposed on one side of an outer peripheral portion of the second substrate so as not to overlap the fixed electrode portion and the support when the second substrate is viewed in a plan view.

11. The physical-quantity sensor according to claim 10,
wherein the one side of the second substrate is provided with a terminal unit that is connected to the outside, and
wherein the terminal unit is disposed to overlap the adhesive when the second substrate is viewed in the plan view.

12. The physical-quantity sensor according to claim 11,
wherein the sensor element is configured to have a first sensor element having a detecting direction in a first direction along a main surface of the second substrate, a second sensor element having a detecting direction in a second direction intersecting with the first direction along the main surface of the second substrate, and a third sensor element having a detecting direction in a third direction intersecting with the first direction and the second direction, and
wherein the third sensor element is disposed in a region farther separated from the one side than the first sensor element and the second sensor element.

13. An electronic device comprising the electronic device according to claim 1.

14. A moving object comprising the electronic device according to claim 1.

15. An electronic device comprising the physical quantity sensor according to claim 10.

16. A moving object comprising the physical quantity sensor according to claim 10.
